(19) United States
(12) Patent Application Publication
(10) Pub. No.: US 2009/0295607 A1
(43) Pub. Date: Dec. 3, 2009

(54) FINDING A VARIABLE LENGTH CODE WITH OPTIMAL ERROR RECOVERY

(75) Inventors: Oscar Chi Lim Au, Hong Kong (CN); Jiantao Zhou, Hong Kong (CN)

Correspondence Address: TUROCY & WATSON, LLP, 127 Public Square, 57th Floor, Key Tower, CLEVELAND, OH, 44114, US

(73) Assignee: THE HONG KONG UNIVERSITY OF SCIENCE AND TECHNOLOGY, Hong Kong (CN)

(21) Appl. No.: 12/131,179

(22) Filed: Jun. 2, 2008

(51) Int. Cl. H03M 7/40

(52) U.S. Cl. 341/67

(57) ABSTRACT

Systems and methodologies for analyzing error recovery performance of variable length codes utilized for encoding and decoding data are provided herein. Synchronization recovery of a set of variable length codes can be evaluated assuming that an encoded bit stream is transmitted over a binary symmetric channel. Further, mean symbol error rates corresponding to each of the variable length codes in the set can be determined based upon the evaluation of the synchronization recovery. Moreover, a subset of the variable length codes with optimal error recovery can be selected as a function of the mean symbol error rates.

### TECHNICAL FIELD

The present disclosure relates generally to analysis of coding schemes, and more particularly to evaluating synchronization recovery capability of variable length codes (VLCs) where an encoded bit stream is transmitted over a binary symmetric channel (BSC).

### BACKGROUND

Variable length codes (VLCs) have been widely used as an efficient compression tool in many practical fields such as image and video coding systems. However, a drawback of VLC is that it has high sensitivity to channel disturbances. Even a single error may propagate for a considerable period, leading to the decoding failure of many consecutive codewords.

In order to reduce the error propagation effect, a variety of techniques have been proposed such as the error-resilient entropy coding (EREC), reversible variable length codes (RVLC), variable-to-fixed length codes, multiplexed codes, self-synchronizing code, and joint source-channel coding for variable length codes. On the other hand, enhancement can also come from the richness of the structures of VLC, namely, a code with good synchronization recovery capability can be selected from among all the equivalent codes, without any loss of coding efficiency. To achieve this goal, appropriate criteria to can be used to determine the synchronization recovery capability of different VLCs. Concerning the quantitative analysis of the synchronization recovery of VLC, research has been conducted in different senses and measures, due to the fact that the range and richness of the structures implicit in VLC make it difficult to identify a general mechanism for synchronization recovery. Early work commonly investigated some intuitive indicators. For instance, a method for estimating expected synchronization delay based on T-code has been evaluated. Aiming to give precise measurements, a state model has been employed, from which a probability generator function was proposed that can be used to obtain the statistical moments of the error span. This model was further simplified such that the mean and the variance of the error span can be obtained via the inversion and multiplication of dimension n−1 square constant matrices. Further, expressions for the mean error propagation length (MEPL, equivalent to the expected error span) and the variance of error propagation length (VEPL, equivalent to the variance of error span) have been proposed by making use of the summation of semi-infinite series. For instance, conventional techniques have presented two design algorithms for finding a code with short (no guarantee of shortest) MEPL and VEPL without sacrificing the coding efficiency.

However, in conjunction with the above described conventional methods for analyzing the synchronization recovery for VLC, a common assumption is that the transmission fault is a single bit inversion error, namely, after an one-bit inversion error, no further bit errors occur until the synchronization is recovered. Clearly, this assumption much simplifies the problem, and the obtained result is a reasonable approximation to that of those situations where the error occurrence rate is very low. Nevertheless, in many scenarios, such as in the Bad state of Gilbert-Elliott model depicting the burst-error channel, the bit error rate is reasonably high. Thus, conventional techniques fail to provide a general analysis that takes into consideration multiple errors or comparably high error rates.

Other common schemes provide a formula for computing E_{rec}, which is the average number of codewords received until the synchronization is recovered, for a binary symmetric channel (BSC) model with a given crossover probability. In addition, a search method based on the suffix condition to find the codes, among equivalent codes, which has seemingly short MEPL, can be provided. It should be pointed out that E_{rec} is defined as the mean value of the total number of incorrectly decoded symbols divided by the number of desync periods. However, the number of desync periods is a random variable that has not yet been studied. Thus, even with E_{rec}, the mean value of the total number of incorrectly decoded symbols or the mean symbol error rate, which is a commonly used metric to assess the error performance of codes when transmitting over various channels, may be unable to be calculated using conventional techniques. Further, since E_{rec} can be interpreted as the average error propagation length in one desync period, the expression of E_{rec}, after some simple transformations, will have the same form as that of the MEPL derived for the single inversion error case, only with different definition of the transition matrix, as shown in Appendix A.

The conventional designs with above-described deficiencies are merely intended to provide an overview of some of the problems encountered in using VLCs, and are not intended to be exhaustive. Other problems with the state of the art may become further apparent upon review of the description of the various non-limiting embodiments of the disclosed subject matter that follows.

### SUMMARY

The following presents a simplified summary of the claimed subject matter in order to provide a basic understanding of some aspects of the claimed subject matter. This summary is not an extensive overview of the claimed subject matter. It is intended to neither identify key or critical elements of the claimed subject matter nor delineate the scope of the claimed subject matter. Its sole purpose is to present some concepts of the claimed subject matter in a simplified form as a prelude to the more detailed description that is presented later.

Systems and methodologies for analyzing error recovery performance of variable length codes utilized for encoding and decoding data are provided herein. Synchronization recovery of a set of variable length codes can be evaluated assuming that an encoded bit stream is transmitted over a binary symmetric channel. Further, mean symbol error rates corresponding to each of the variable length codes in the set can be determined based upon the evaluation of the synchronization recovery. Moreover, a subset of the variable length codes with optimal error recovery can be selected as a function of the mean symbol error rates.

To the accomplishment of the foregoing and related ends, certain illustrative aspects of the claimed subject matter are described herein in connection with the following description and the annexed drawings. These aspects are indicative, however, of but a few of the various ways in which the principles of the claimed subject matter can be employed. The claimed subject matter is intended to include all such aspects and their equivalents. Other advantages and novel features of the claimed subject matter can become apparent from the following detailed description when considered in conjunction with the drawings.

### BRIEF DESCRIPTION OF THE DRAWINGS

Various non-limiting embodiments are further described with reference to the accompanying drawings in which:

FIG. 1 is an illustration of an example system that evaluates synchronization recovery of variable length codes (VLCs);

FIG. 2 is an illustration of an example encoding and decoding procedure, where the symbols are encoded by a VLC;

FIG. 3 is an illustration of an example state transition table (e.g., example extended transition matrix) with probabilities associated with transitions from state i to state j;

FIG. 4 is an illustration of an example table that includes example Huffman codes for a five-character source;

FIG. 5 is an illustration of an example table that represents reception error with bit inversion;

FIG. 6 is an illustration of an example state transition table;

FIGS. 7-9 illustrate various simulations comparing theoretical results with numerical simulations for the five-character source;

FIG. 10 is an illustration of an example table that includes example Huffman codes for the English alphabet source;

FIGS. 11-12 illustrate various simulations comparing theoretical results with numerical simulations for the English alphabet source;

FIG. 13 is an illustration of an example table that includes example Huffman codes for a Geometric source;

FIGS. 14-17 illustrate various simulations of MSER and MEPL per erroneous bit for the stable code and unstable code with different alphabet sizes N;

FIG. 18 is an illustration of an example table showing the Geometric source and the stable/unstable code;

FIG. 19 is an illustration of a simulation result of MEPL with respect to a decimal representation of an ending vector E for the Geometric source;

FIG. 20 is an illustration of an example methodology that facilitates optimizing error recovery performance based upon selection of variable length code utilized for encoding and decoding data;

FIG. 21 is an illustration of an example methodology that facilitates analyzing error recovery performance of variable length codes;

FIG. 22 is a block diagram of an example operating environment in which various aspects described herein can function;

FIG. 23 illustrates an example wireless communication network in which various aspects described herein can be utilized; and

Appendices A, B, C, D, E, and F describe various exemplary non-limiting, aspects, and these appendices are to be considered part of the specification of the subject application.

### DETAILED DESCRIPTION

The claimed subject matter is now described with reference to the drawings, wherein like reference numerals are used to refer to like elements throughout. In the following description, for purposes of explanation, numerous specific details are set forth in order to provide a thorough understanding of the claimed subject matter. It may be evident, however, that the claimed subject matter may be practiced without these specific details. In other instances, well-known structures and devices are shown in block diagram form in order to facilitate describing the claimed subject matter.

As used in this application, the terms “component,” “system,” and the like are intended to refer to a computer-related entity, either hardware, a combination of hardware and software, software, or software in execution. For example, a component may be, but is not limited to being, a process running on a processor, a processor, an object, an executable, a thread of execution, a program, and/or a computer. By way of illustration, both an application running on a server and the server can be a component. One or more components may reside within a process and/or thread of execution and a component may be localized on one computer and/or distributed between two or more computers. Also, the methods and apparatus of the claimed subject matter, or certain aspects or portions thereof, may take the form of program code (i.e., instructions) embodied in tangible media, such as floppy diskettes, CD-ROMs, hard drives, or any other machine-readable storage medium, wherein, when the program code is loaded into and executed by a machine, such as a computer, the machine becomes an apparatus for practicing the claimed subject matter. The components may communicate via local and/or remote processes such as in accordance with a signal having one or more data packets (e.g. data from one component interacting with another component in a local system, distributed system, and/or across a network such as the Internet with other systems via the signal).

Synchronization recovery capability of variable length code (VLC) has been considered as an important performance and design criterion in addition to its coding efficiency. However, almost all of the existing methods for analyzing the synchronization recovery capability of VLC assume that the transmission fault is a random single bit inversion, namely, after an one-bit inversion error, no further errors occur until synchronization is achieved. Accordingly, the subject disclosure enables more precise evaluation of the synchronization recovery capability of VLC, assuming that the encoded bit stream is transmitted over binary symmetric channel (BSC). By making use of the Perron-Frobenius Theorem, a very simple expression can be derived for the exact mean symbol error rate (MSER). Further, the variance of symbol error rate (VSER) can be determined to equal zero as long as the input symbol length n→∞. In particular, for large n, the decay rate of VSER is almost inversely proportional to n. Furthermore, a linkage between MSER and mean error propagation length (MEPL) obtained under the single inversion error assumption can be established, by proving that MEPL becomes a scaled value of MSER as the crossover probability of BSC tends to zero.

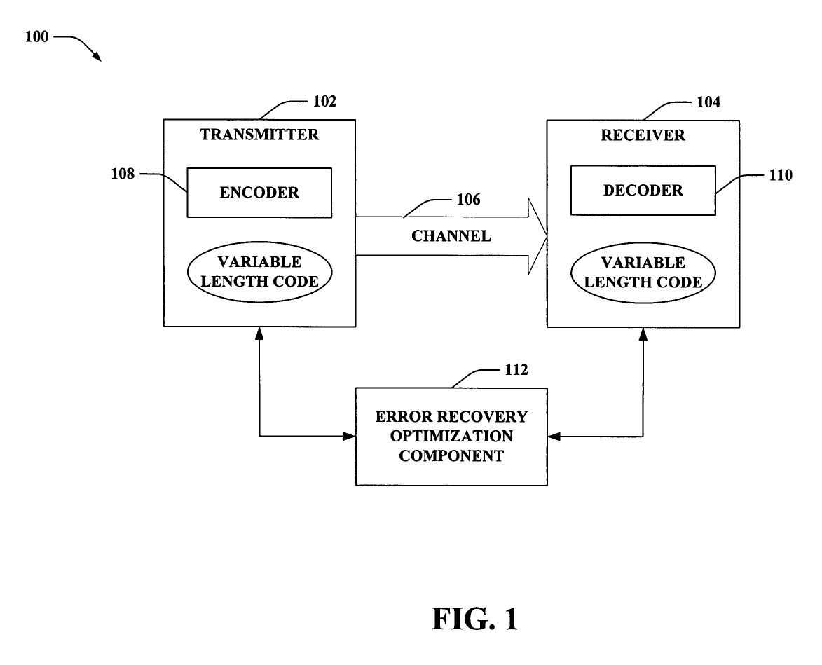

Now referring to FIG. 1, illustrated is a system 100 that evaluates synchronization recovery of variable length codes (VLCs). The system 100 includes a transmitter 102 (e.g., source, . . . ) that communicates with a receiver 104 (e.g., target, . . . ) via a channel 106. It is to be appreciated that any type of data can be transferred between the transmitter 102 and the receiver 104. For example, the transmitter 102 and the receiver 104 can each be one or more of a computing device (e.g., personal computer, a laptop, a handheld computing device, . . . ), a telephone (e.g., a cellular phone, a smart phone, a wireless phone, . . . ), a handheld communication device, a gaming device, a personal digital assistant (PDA), a teleconferencing system, a consumer product, an automobile, a mobile media player (e.g., MP3 player, . . . ), a camera (e.g., still image camera and/or video camera, . . . ), a server, a network node, or the like. Although one transmitter 102 and one receiver 104 are depicted, it is to be appreciated that the system 100 can include any number of transmitters similar to the transmitter 102 and/or any number of receivers similar to the receiver 104. Moreover, according to an example, it is contemplated that the transmitter 102 and the receiver 104 can be substantially similar to each other (e.g. each can be a transceiver, . . . ); however, the claimed subject matter is not limited to the aforementioned example.

The transmitter 102 can further include an encoder 108 that encodes data for transmission. For instance, the transmitter 102 can obtain, generate, retrieve from memory, etc. input symbol(s); thereafter, the encoder 108 can yield encoded data based upon the input symbol(s) that can be transmitted over the channel 106. The encoder 108 can utilize a variable length code for encoding data for transfer over the channel 106. The receiver 104 can obtain the data transmitted over the channel 106. Moreover, the receiver 104 can include a decoder 110 that decodes the received data to yield decoded symbol(s). The decoder 110 can leverage a variable length code for decoding the received data. However, transmission errors can result in the decoded symbol(s) differing from the input symbol(s). Accordingly, the system 100 can enable utilizing variable length codes with good synchronization recovery.

The system 100 can also include an error recovery optimization component 112 that analyzes synchronization recovery capability of VLCs. The error recovery optimization component 112 can determine a mean symbol error rate (MSER) and an associated variance of symbol error rate (VSER) associated with a VLC. The MSER and VSER can provide two measures by which the error recovery optimization component 112 can evaluate the synchronization recovery capability of VLC transmitted over a binary symmetric channel (BSC) with any crossover probability. By making use of the Perron-Frobenius Theorem, a simple expression for the MSER can be derived. Further, as shown below, VSER can equal zero as long as the input symbol length n→∞. Particularly, as illustrated in the following discussion, for large n, the decay rate of VSER can be nearly inversely proportional to n, independent with the source distribution and the code structure. Furthermore, the mean error propagation length (MEPL) derived for the single inversion error case can become a scaled value of MSER as the crossover probability of the BSC tends to zero.

By way of example, the error recovery optimization component 112 can evaluate MSER, VSER, and/or MEPL of a set of variable length codes over BSC. In contrast, conventional techniques for evaluating synchronization recovery oftentimes considered transmission fault to be a single bit inversion. Moreover, based upon this evaluation of MSER, VSER, and/or MEPL over BSC, the error recovery optimization component 112 can select a subset of variable length codes (e.g., one or more variable length codes can be identified, . . . ) that yield optimal synchronization recovery capability when employed to encode and decode data transmitted from the transmitter 102 to the receiver 104 via the channel 106. The selected subset of variable length codes can thereafter be used by the transmitter 102 and/or receiver 104.

Pursuant to an illustration, the error recovery optimization component 112 can identify the optimized subset of variable length codes prior to operation of the transmitter 102 and the receiver 104 (e.g., the optimized subset of variable length codes can be determined, the optimized subset can be indicated and/or provided to the transmitter 102 and/or receiver 104, and thereafter transmission of data encoded and decoded via utilizing the optimized subset can be effectuated, . . . ). Following this illustration, the error recovery optimization component 112 can be employed to initialize the transmitter 102 and/or the receiver 104; however, the claimed subject matter is not so limited. In accordance with another example, the error recovery component 112 can analyze synchronization recovery of variable length codes used by the transmitter 102 and/or the receiver 104 when encoding and/or decoding data, and thus, the error recovery optimization component 112 can provide feedback control to enable the system 100 to converge towards employing one or more optimal variable length codes. Further, for instance, the error recovery optimization component 112 can optimize synchronization recovery in real-time based upon variable length code selection that leverages the aforementioned feedback control; thus, the error recovery optimization component 112 can tailor the variable length code selection upon change of conditions associated with the system 100 (e.g., change in source such as five-character source, English source, Geometric source, etc., variation in error rate, differences in available libraries of variable length codes that can be used by differing transmitter/receiver pairs, . . . ).

Pursuant to another illustration, for a Geometric source, the error recovery optimization component 112 can identify that a stable code yields the best error recovery performance for the case of bit inversion among all Huffman codes for this source as described herein. Moreover, the error recovery optimization component 112 can determine that the unstable code yields the worst error recovery performance as further described below. Thus, the error recovery optimization component 112 can select the stable code for use by the transmitter 102 and the receiver 104.

Although shown as being separate from the transmitter 102 and the receiver 104, it is contemplated that the transmitter 102 can include the error recovery optimization component 112 (or a portion thereof) and/or the receiver 104 can include the error recovery optimization component 112 (or a portion thereof).

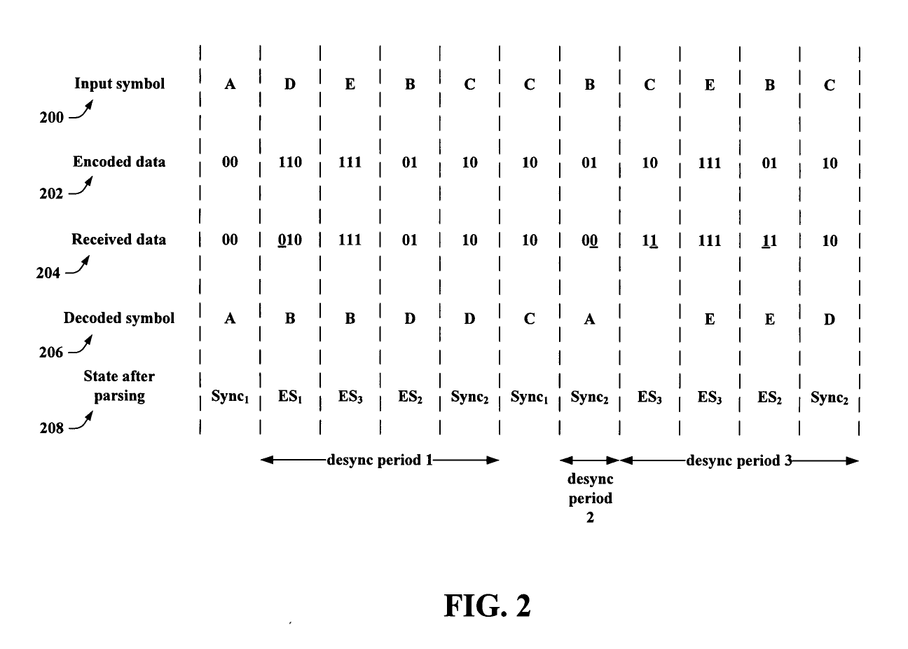

FIG. 2 illustrates an example encoding and decoding procedure, where the symbols are encoded by the VLC {A: 00, B: 01, C: 10, D: 110, E: 111}. Row 200 includes a plurality of input symbols (e.g., sequence of symbols, . . . ). Each input symbol can be encoded (e.g., by the encoder 108 of FIG. 1 using the VLC, . . . ) as shown in row 202; the encoded data from row 202 can thereafter be transferred via a channel to a receiver (e.g., the receiver 104 of FIG. 1, . . . ). Received data is shown in row 204. For instance, bit inversion errors can be introduced into the data during transmission; thus, example bit inversion errors are illustrated in row 204 as being underlined. The received data can be decoded to yield decoded symbols included in row 206. Moreover, a state after parsing is shown in row 208.

As there are no bit errors in the codeword of the first symbol A, the first two bits can be decoded correctly, and the decoding of the next symbol will start from the correct location. However, since the first bit of the codeword of the second symbol D is flipped (e.g., ‘1’ is replaced by ‘0’), the third and the fourth bit ‘01’ will be parsed into symbol B; meanwhile, the following bit ‘0’, which is part of the encoded data for the second symbol D, remains undecodable. Thus, the decoder enters into a desynchronization status. When the bits of the third symbol E arrive, the remained ‘0’ will be appended as a prefix, thus, making the subsequent decoding start from a wrong position. Then, the error propagation phenomenon arises. The parsing error will continue until decoding of the fifth symbol C, since the last bit of the decoded code sequence coincides with the last bit of the correct code sequence. In this case, the synchronization is recovered, and the block of symbols starting from the second symbol to the fifth symbol can be referred to as desync period 1. After that, if there are further bit errors, the decoder will go into the desynchronization status again, and after a certain time, the synchronization will be reestablished. As described herein, variable length codes with good synchronization recovery capability can be selected for use in conjunction with encoding and decoding symbols based upon analysis of MSER and/or VSER.

The following notation conventions are adopted for consistency and clarity herein. Denote X [symbol] Y as the bit concatenation of two binary sequences X and Y. Let the source alphabet be A={a₁, a₂, . . . , a_{N}}, and let the probability mass function of this source be p(a₁), p(a₂), . . . , p(a_{N}). The source is encoded by the binary prefix code C={c₁, c₂, . . . , c_{N}}, where cᵢ is the codeword of aᵢ. Let

$${C}^{*} {=}^{Δ} {{⋃}^{∞}}_{n = 0} {C}^{n} ,$$

where Cⁿ denotes the set of all sequences obtained by concatenating n codewords of C. The elements in C* are called sentences.

A binary prefix code can be represented by a binary branching tree, where each node either gives rise to other nodes or does not. A first type of node is called an internal node and the second type of node is called leaf node or external node. As described herein, a binary exhaustive prefix code where each node either has two children or no children is typically considered; however, the claimed subject matter is not so limited.

Given a code C, a largest codeword length can be defined as Lₘₐₓ=max{l(c)|c ε C}, where l(c) is the length of c, and a length vector can be defined as L=(L₁, L₂, . . . , L_{L}_{ₘₐₓ}), where Lᵢ is the number of codewords with length i. Let

$${Θ}^{*} {=}^{Δ} {⋃}_{n : {L}_{n} > 0} {\{ 0 , 1 \}}^{n}$$

be the set of all possible received codewords when C is transmitted over BSC.

For two m×n matrices R={r_{i,j}} and S={s_{i,j}}, if r_{i,j}≧s_{i,j} for all i, j, then this can be referred to as R≧S. If, in fact, r_{i,j}>s_{i,j} for all i,j, such scenario can be indicated as R>S.

For an n×n matrix T={t_{i,j}}, T^{k}={t_{i,j}^{(k)}} can be denoted as the kth power. A non-negative matrix T is called irreducible if, for every ordered pair (i,j) from the index set {1,2, . . . , n}, there exists a positive integer m≡m(i, j) such that t_{i,j}^{(m)}>0. A non-negative matrix T is called primitive if there exists a positive integer k such that T^{k}>0, where 0 denotes the matrix with all zero entries. A non-negative matrix T is called stochastic if

$${\sum }_{j} {t}_{i , j} = 1 ,$$

for all i.

For an n×n matrix T={t_{i,j}} suppose there exists a real or complex number λ such that λu′=u′T and λv=Tv, for some vectors u and v, where (·)′ stands for the transpose of the corresponding matrix. Then λ is called an eigenvalue of T, and u (v, respectively) is called a left (right) eigenvector of T. The largest eigenvalue λ in magnitude of a primitive matrix is called the Perron-Frobenius (PF) eigenvalue, and according to the Perron-Forbenius Theorem, λ is a real positive number. The associated unique left and right eigenvectors u and v respectively are called PF left and PF right eigenvectors, if u and v are positive componentwise and

$${u}^{′} {1}_{n} = {u}^{′} v = 1 , \\ where$$

$${1}_{n} = {( \underbrace{1 , 1 , … , 1}_{n} )}^{′} .$$

Again referring to the example shown in FIG. 2, there are three possible cases when the decoder parses a codeword received from BSC.

1) The codeword is correctly decoded. In this case, the state after parsing is called synchronization state without error, which is denoted by Sync₁ in row 208;

2) The codeword is incorrectly decoded, but all the received bits are consumed. In this case, the state after parsing is called synchronization state with error, which is denoted by Sync₂ in row 208;

3) The codeword is incorrectly decoded and not all received bits are consumed. The remaining undecodable bits will match one of the internal nodes of the binary branching tree corresponding to the VLC. Since these bits will influence the decoding of the next symbols, in this case, the state after parsing can be referred to as error state i (ESᵢ), where i is the index of the internal node that the remaining bits match.

As described herein, correctly decoded can mean that the decoded symbol is exactly the same as the encoded symbol. Even though, appended with previously remaining bits as a prefix, the received codeword can be decoded as a correct symbol concatenated with a sentence or a sentence followed by a string of undecodable bits (e.g., the first decoded symbol in desync period 3 shown in FIG. 2), this case is not treated as correct decoding. In other words, all symbols decoded in the desync periods of FIG. 2 are considered to be wrong (e.g., synchronization can be considered in the Levenshtein sense, . . . ).

In FIG. 2, the three kinds of states for a specific VLC are illustrated. In general, the set of states can be written as:

S={ES₁,ES₂, . . . ,ES_{M},Sync₂,Sync₁} (1)

where M=N−2 is the number of internal nodes, and N is the alphabet size. Each element Sᵢ in S (always ordered as in Equation (1)) corresponding to state i is associated with a string of bits Bᵢ, 1≦i≦N, where, for 1≦i≦M, Bᵢ is the corresponding bit representation of the internal node i, and for i=N−1 and i=N, Bᵢ is an empty string.

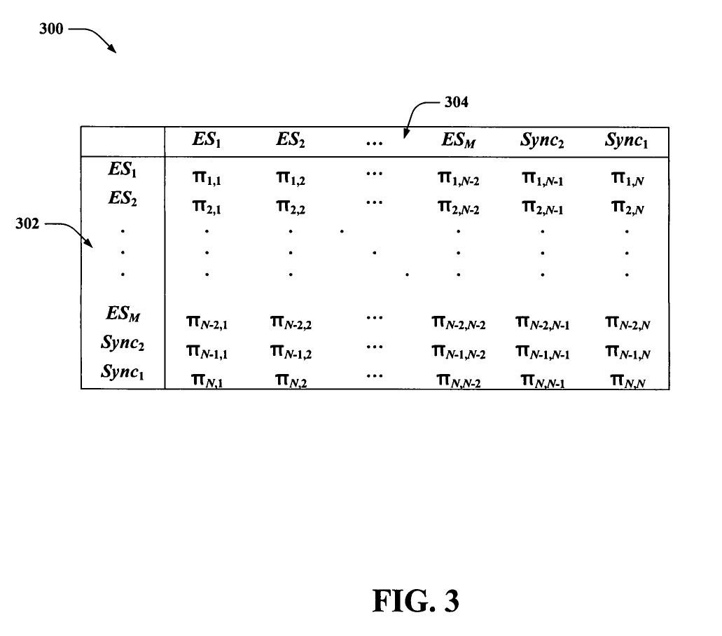

The source can be assumed to be memoryless and the source data can be assumed to be generated randomly according to the probability mass function. Unless otherwise stated, in the sequel, bit error means bit inversion error, or so-called amplitude error. Since the bit errors may occur anywhere in the bit stream with equal probability, the sequence of states forms a Markov chain. Let π_{i,j}, 1≦i,j≦N, be the transition probability from state i to state j. The state transition can generally be described as a state transition table, which can also be referred to as an extended transition matrix. FIG. 3 illustrates an example state transition table 300 (e.g., example extended transition matrix 300) with probabilities associated with transitions from state i to state j. As shown, column 302 includes possibilities for state i and row 304 includes possibilities for state j. It should be noted that the extended transition matrix 300 includes all possible states (e.g., ES₁,ES₂, . . . ,ES_{M},Sync₂,Sync₁, . . . ), which differs from an error state transition matrix; an error state transition matrix commonly includes only transition probabilities between error states. Let

$$\begin{matrix}{Ω}_{θ} ( i , j ) = \{ θ ∈ {Θ}^{*} : ∃ {c}^{*} ∈ {C}^{*} such that {B}_{i} ⊗ θ = {c}^{*} ⊗ {B}_{j} \} \\ = \{ {θ}_{1} , {θ}_{2} , … , {θ}_{\vert {Ω}_{θ} ( i , j ) \vert} \}\end{matrix} \qquad ( 2 )$$

where |▪| denotes the cardinality of a set.

Then,

$${π}_{i , j} = {\sum }_{( h , k ) : {θ}_{h} ∈ {Ω}_{θ} ( i , j ) , {c}_{k} ∈ C , l ( {c}_{k} ) = l ( {θ}_{h} )} p ( {a}_{k} ) {{p}_{e}^{{d}_{H} ( {θ}_{h} , {c}_{k} )} ( 1 - {p}_{e} )}^{l ( {c}_{k} ) - {d}_{H} ( {θ}_{h} , {c}_{k} )} \qquad ( 3 )$$

where pₑ is the crossover probability of BSC, and d_{H} stands for the Hamming distance.

As described herein, without loss of generality, it is assumed that the VLC does not contain an infinite loop of error states. In other words, starting from any error state, the probability of entering into (not necessarily in one jump) a synchronization state is non-zero. Further, it can be assumed that from any synchronization state, the probability of visiting any error state is non-zero. Otherwise, an error state that can never be reached could exist, and hence, such error state can be removed from the set of states. Concerning the extended transition matrix, four Lemmas which are of great use below are presented.

Lemma 1: Extended transition matrix is primitive.

Proof: See Appendix B.

Remark: It can be verified that this conclusion also holds for the error state transition matrix of the single error case.

Lemma 2: Let N×N matrix II={π_{i,j}} be the extended transition matrix for a VLC with alphabet size N. Thus,

$${lim}_{k \to ∞} {\prod }^{k} = {vu}^{′} = {1}_{N} {u}^{′} \qquad ( 4 )$$

where u and v are, respectively, the PF left and PF right eigenvectors.

Proof: See Appendix C.

Remark: Conventional methods for calculating the MEPL for VLC oftentimes are based on the summation of a semi-infinite series, which converges when the error state transition matrix T satisfies lim_{n→∞} Tⁿ=lim_{n→∞} nTⁿ=0. For instance, a very complicated proof of lim_{n→∞} Tⁿ=lim_{n→∞} nTⁿ=0 by mathematical induction has been provided in conjunction with such common methods. However, the proof can be much simplified by using a similar technique shown in Appendix C, which relies on the Perron-Frobenius Theorem. Since T only consists of the transition probabilities between the error states, the PF eigenvalue 0<λ<1. Otherwise, the MEPL is infinity. Thus, lim_{n→∞} λⁿ=0. Notice T is primitive, which follows that lim_{n→∞} Tⁿ=lim_{n→∞} λⁿvu′=0. It is straightforward to extend the results to prove lim_{n→∞} nTⁿ=0.

If the VLC does not contain an infinite loop of error states, and every state is reachable, the condition that (I−Q)⁻¹ exists can be removed. For instance, lim_{k→∞} Q^{k}=0 can guarantee the existence of (I−Q)⁻¹.

Lemma 3: Let N×N matrix II={π_{i,j}} be the extended transition matrix for a VLC with alphabet size N. Suppose u=(u₁, u₂, . . . , u_{N})′ is the PF left eigenvector, and s₁ is the last column of II, e.g., s₁=(π_{1,N},π_{2,N}, . . . π_{N,N})′. Hence,

u′s₁=u_{N} (5)

Proof: See Appendix D

Lemma 4: Let N×N matrix II={π_{i,j}} be the extended transition matrix for a VLC with alphabet size N. The following two limiting equations hold

$$\begin{matrix}{lim}_{{p}_{e} \to 0} \frac{1 - {π}_{N , N}}{{p}_{e} {L}_{X} ( C )} = 1 \\ and & ( 6 ) \\ {lim}_{{p}_{e} \to 0} \frac{{π}_{N , j}}{{p}_{e} {L}_{X} ( C )} = {\sum }_{( h , k ) : {θ}_{h} ∈ {Ω}_{θ} ( N , j ) , {c}_{k} ∈ C , l ( {c}_{k} ) = l ( {θ}_{h} ) , {d}_{H} ( {θ}_{h} , {c}_{k} ) = 1} \frac{p ( {a}_{k} )}{{L}_{X} ( C )} , 1 \leq j \leq N - 2 & ( 7 )\end{matrix}$$

where

$${L}_{X} ( C ) = {\sum }_{i = 1}^{N} p ( {a}_{i} ) l ( {c}_{i} )$$

is the expected codeword length.

Proof: See Appendix E

The following describes calculation of MSER and VSER. Conventionally, the mean and the variance of error span have been proposed to measure the synchronization recovery capability of VLC, under the assumption that the transmission fault is a single bit inversion. In contrast, the claimed subject matter relates to defining the mean symbol error rate (MSER) and the variance of symbol error rate (VSER) to measure the synchronization recovery capability of VLC transmitting over BSC. Thus, the mean value is taken over all possible source data and all possible bit error positions with respect to the source distribution and the distribution of the bit error occurrence.

More formally, the total error propagation length T(n) can be defined as the total number of incorrectly decoded symbols when the input symbol length is n. For the example in FIG. 2, n=11 and T(n)=9. MSER is then defined as

$$μ = {lim}_{n \to ∞} \frac{E \{ T ( n ) \}}{n} \qquad ( 8 )$$

The associated VSER can then be defined as

$${σ}^{2} = {lim}_{n \to ∞} \frac{{σ}_{T}^{2} ( n )}{{n}^{2}} \qquad ( 9 )$$

where σ_{T}²(n) denotes the variance of T(n).

Theorem 1: Suppose the VLC encoded bit stream is transmitted over BSC, and N×N matrix II={π_{i,j}} is the corresponding extended transition matrix. The MSER for this VLC is given by

μ=1−u_{N} (10)

where u_{N} is the last element of the PF left eigenvector u of II.

Proof: Let pᵢ(n), n≦1, be the probability of ending up with state i after parsing the nth codewords. According to the extended transition matrix, this can lead to p(n)=p(n−1)II, where p(j)=(p₁(j), p₂(j), . . . , p_{N}(j)). The aforementioned can be written as p(n)=p(1)IIⁿ⁻¹.

Clearly T(n) is a non-decreasing function with respect to the input symbol length n, and thus,

T(n+1)=T(n)+Δ(n) (11)

where n≧0 and Δ(n)ε{0,1}, with initial value T(0)=0.

From the synchronization recovery process, it can be found that only when the state after parsing the (n+1)th codeword is Sync₁, then Δ(n)=0. Otherwise, Δ(n)=1. Hence, the probability mass function of Δ(n) can be obtained, such as:

$$\begin{matrix}Pr \{ Δ ( n ) = 0 \} = \{ \begin{matrix}{\sum }_{i = 1}^{N} p ( {a}_{i} ) {( 1 - {p}_{e} )}^{l ( {c}_{i} )} & for n = 0 \\ p ( n ) {s}_{1} & for n \geq 1\end{matrix} \\ and & ( 12 ) \\ Pr \{ Δ ( n ) = 1 \} = \{ \begin{matrix}1 - {\sum }_{i = 1}^{N} p ( {a}_{i} ) {( 1 - {p}_{e} )}^{l ( {c}_{i} )} & for n = 0 \\ 1 - p ( n ) {s}_{1} & for n \geq 1\end{matrix} & ( 13 )\end{matrix}$$

where s₁=(π_{1,N}, π_{2,N}, . . . , π_{N,N})′ is the last column of II.

Taking expectation on Equation (11), can yield

$$\{ \begin{matrix}E \{ T ( n ) \} = E \{ T ( n - 1 ) \} + [ 1 - p ( n - 1 ) {s}_{1} ] \\ E \{ T ( n - 1 ) \} = E \{ T ( n - 2 ) \} + [ 1 - p ( n - 2 ) {s}_{1} ] \\ ⋮ \\ E \{ T ( 2 ) \} = E \{ T ( 1 ) \} + [ 1 - p ( 1 ) {s}_{1} ]\end{matrix} \qquad ( 14 )$$

Adding these equations together results in the following:

$$E \{ T ( n ) \} = n - 1 + E \{ T ( 1 ) \} - p ( 1 ) ( {\sum }_{i = 0}^{n - 2} {\prod }^{i} ) {s}_{1} \qquad ( 15 )$$

Notice that 0≦E{T(1)}≦1, which implies

$$\begin{matrix}μ = {lim}_{n \to ∞} \frac{E \{ T ( n ) \}}{n} \\ = 1 - p ( 1 ) ( {lim}_{n \to ∞} \frac{1}{n} {\sum }_{i = 0}^{n - 2} {\prod }^{i} ) {s}_{1} \\ {=}^{( a )} 1 - p ( 1 ) {1}_{N} {u}^{′} {s}_{1} \\ {=}^{( b )} 1 - {u}^{′} {s}_{1} \\ {=}^{( c )} 1 - {u}_{N}\end{matrix} \qquad ( 16 )$$

where (a) follows from Lemma 2, (b) holds as all the probabilities sums up to 1, and (c) follows from Lemma 3.

Lemma 5: For T(n) and Δ(n) defined above, the following can result:

$${lim}_{n \to ∞} \frac{Cov \{ T ( n ) , Δ ( n ) \}}{n} = 0 \qquad ( 17 )$$

Proof: See Appendix F.

Theorem 2: Suppose the VLC encoded bit stream is transmitted over BSC, and N×N matrix II={π_{i,j}} is the corresponding extended transition matrix. The VSER for this VLC is given by:

σ²=0 (18)

Proof: From Equation (11), for n≧1, the following can be yielded:

$$\begin{matrix}{σ}_{T}^{2} ( n + 1 ) = {σ}_{T}^{2} ( n ) + {σ}_{Δ}^{2} ( n ) + 2 Cov \{ Δ ( n ) , T ( n ) \} \\ = {σ}_{T}^{2} ( n ) + p ( 1 ) {\prod }^{n - 1} {s}_{1} - {[ p ( 1 ) {\prod }^{n - 1} {s}_{1} ]}^{2} + 2 Cov \\ \{ Δ ( n ) , T ( n ) \}\end{matrix} \qquad ( 19 )$$

By using a similar technique to derive Equation (15), the following can be obtained:

$${σ}_{T}^{2} ( n ) = {σ}_{T}^{2} ( 1 ) + p ( 1 ) {\sum }_{i = 0}^{n - 2} {\prod }^{i} {s}_{1} - {\sum }_{i = 0}^{n - 2} {[ p ( 1 ) {\prod }^{i} {s}_{1} ]}^{2} + 2 {\sum }_{i = 1}^{n - 1} Cov \{ Δ ( i ) , T ( i ) \} \qquad ( 20 )$$

Notice that 0≦σ_{T}²(1)≦1, which implies

$${lim}_{n \to ∞} \frac{{σ}_{T}^{2} ( n )}{{n}^{2}} = {lim}_{n \to ∞} \frac{p ( 1 ) {\sum }_{i = 0}^{n - 2} {\prod }^{i} {s}_{1} - {\sum }_{i = 0}^{n - 2} {[ p ( 1 ) {\prod }^{i} {s}_{1} ]}^{2}}{{n}^{2}} + 2 {lim}_{n \to ∞} \frac{{\sum }_{i = 1}^{n - 1} Cov \{ Δ ( i ) , T ( i ) \}}{{n}^{2}} {=}^{( a )} {lim}_{n \to ∞} \frac{p ( 1 ) {1}_{N} {u}^{′} {s}_{1} - {[ p ( 1 ) {1}_{N} {u}^{′} {s}_{1} ]}^{2}}{n} + 2 {lim}_{n \to ∞} \frac{Cov \{ Δ ( n ) , T ( n ) \}}{n} {=}^{( b )} {lim}_{n \to ∞} \frac{{u}_{N} - {u}_{N}^{2}}{n} = 0 \qquad ( 21 )$$

where (a) follows from Lemma 2, and (b) follows from Lemmas 3 and 5. This completes the proof.

Remark: From Theorem 2, it can be seen that the symbol error rate becomes a deterministic value as the input symbol length goes to infinity, irrespective of the source distribution and code structure. In addition, from (21), it can be seen that, for large n, the decay rate of the variance is nearly proportional to 1/n.

Under the single error assumption, the MEPL and VEPL, normally, have been shown to be different for different VLCs. Hence, using MEPL and VEPL as criteria to measure the synchronization recovery capability of two VLCs, MEPL and VEPL have to be considered simultaneously. However, MSER and VSER are used as criteria, MSER which is in a very simple form can be considered, as VSER is zero for any VLC. This may be helpful to simplify the task of finding a VLC with best synchronization recovery capability.

In the next Theorem, a relationship between the MSER derived above and the MEPL obtained for single error case can be established.

Theorem 3: Let μ and μₛ, respectively, be the MSER and MEPL for a VLC. Then

$${lim}_{{p}_{e} \to 0} \frac{μ}{{p}_{e} {L}_{X} ( C )} = {μ}_{s} \qquad ( 22 )$$

where pₑ is the crossover probability of the BSC, and L_{X}(C) is the expected codeword length.

Proof: Let the alphabet size of the VLC be N. Thus,

μₛ=1+\vec{p}(I−Q)⁻¹1_{M} (23)

where \vec{p}=(p(α₁), . . . , p(α_{M})), with p(αᵢ) being the probability that the codeword containing a bit error ends up with ESᵢ after parsing (e.g., p(αᵢ) can be interpreted as the transition probability from the initial state to error state ESᵢ, such as p(αᵢ)=Pr{I→ESᵢ}, where I denotes the initial state, . . . ); Q is the error state transition matrix for single error case; and M=N−2 is the number of error states.

Hence, it suffices to prove

$${lim}_{{p}_{e} \to 0} \frac{μ}{{p}_{e} {L}_{X} ( C )} = 1 + {\vec{p} ( I - Q )}^{- 1} {1}_{M} \qquad ( 24 )$$

Let N×N matrix II={π_{i,j}} be the extended transition matrix when this VLC encoded bit stream is transmitted over BSC, and u=(u₁, u₂, . . . , u_{N})′ be the PF left eigenvector. Notice that from any error state, it may be impossible to jump in one step to the synchronization state without error (Sync₁). In addition, the transition probability from Sync₁ to any state is equal to that from Sync₂ to that state. It implies

π_{j,N}=0 for all 1≦j≦N−2 π_{N-1,j}=π_{N,j} for all 1≦j≦N (25)

Equation (25), and the fact that the PF eigenvalue for II is λ=1, can yield

(I−R′)uₑ=r(u_{N-1}+u_{N}) (26)

where

$$R = ( \begin{matrix}{π}_{1 , 1} & {π}_{1 , 2} & ⋯ & {π}_{1 , M} \\ {π}_{2 , 1} & {π}_{2 , 2} & ⋯ & {π}_{2 , M} \\ ⋮ & ⋮ & ⋰ & ⋮ \\ {π}_{M , 1} & {π}_{M , 2} & ⋯ & {π}_{M , M}\end{matrix} )$$

is a sub-matrix of the extended transition matrix II, consisting only of the transition probabilities between error states;

uₑ=(u₁, u₂, . . . , u_{M})′

and

r=(π_{N,1}, π_{N,2}, π_{N,M})′

Then

$${\sum }_{i = 1}^{M} {u}_{i} = {1}_{M}^{′} {( I - {R}^{′} )}^{- 1} r ( {u}_{N - 1} + {u}_{N} ) \qquad ( 27 )$$

As

$${\sum }_{i = 1}^{N} {u}_{i} = 1$$

by definition, the following can be obtained:

$${\sum }_{i = 1}^{M} {u}_{i} = \frac{{1}_{M}^{′} {( I - {R}^{′} )}^{- 1} r}{1 + {1}_{M}^{′} {( I - {R}^{′} )}^{- 1} r} \qquad ( 28 )$$

On the other hand, from Lemma 4, it can be found that:

$${lim}_{{p}_{e} \to 0} \frac{r}{{p}_{e} {L}_{X} ( C )} = {\vec{p}}^{′} \qquad ( 29 )$$

Consequently

$${lim}_{{p}_{e} \to 0} \frac{μ}{{p}_{e} {L}_{X} ( C )} {=}^{( a )} {lim}_{{p}_{e} \to 0} \frac{1 - {u}_{N}}{{p}_{e} {L}_{X} ( C )} {=}^{( b )} {lim}_{{p}_{e} \to 0} \frac{1 - ( {u}_{N - 1} + {u}_{N} ) {π}_{N , N}}{{p}_{e} {L}_{X} ( C )} {=}^{( c )} {lim}_{{p}_{e} \to 0} \frac{1 - {π}_{N , N}}{{p}_{e} {L}_{X} ( C )} + {lim}_{{p}_{e} \to 0} \frac{{π}_{N , N} {\sum }_{i = 1}^{M} {u}_{i}}{{p}_{e} {L}_{X} ( C )} {=}^{( d )} 1 + {1}_{M}^{′} {( I - {lim}_{{p}_{e} \to ∞} {R}^{′} )}^{- 1} {\vec{p}}^{′} = 1 + {\vec{p} ( I - {lim}_{{p}_{e} \to ∞} R )}^{- 1} {1}_{M} {=}^{( e )} 1 + {\vec{p} ( I - Q )}^{- 1} {1}_{M} \qquad ( 30 )$$

where (a) follows from Theorem 1, (b) follows from Lemma 3 and Equation (25), (c) follows from

$${\sum }_{i = 1}^{N} {u}_{i} = 1 ,$$

(d) follows from Lemma 4, Equation (28), Equation (29), and the fact that

$${lim}_{{p}_{e} \to 0} {π}_{N , N} = 1 ,$$

(e) follows from Equation (3). This completes the proof.

Remark: From this Theorem, it can be seen that the MEPL for single error case can be treated as a scaled version of MSER when the crossover probability of BSC tends to zero.

The intuitive interpretation of this Theorem can be as follows. Define

$$γ = \frac{μ}{{p}_{e} {L}_{X} ( C )} = \frac{n μ}{{p}_{e} {nL}_{X} ( C )}$$

as the mean error propagation length per erroneous bit (MEPL per erroneous bit), where the numerator nμ is the total number of incorrectly decoded symbols, and the denominator pₑnL_{X}(C) is the total number of erroneous bits. When pₑ is close to zero, the erroneous bits are very sparsely distributed in the bit stream. As the error propagation length induced by single error is of finite length, the MEPL per erroneous bit approaches the MEPL for single error case.

Further, Equation (22) provides a simple way to estimate the MSER when pₑ is small, that is, μ≈μₛL_{X}(C)pₑ, which is linearly increasing with pₑ.

Smaller MEPL does not necessarily mean smaller MSER, as MSER is also a function of L_{X}(C). Hence, comparing two VLCs with different expected codeword length, if one VLC has smaller MEPL, the synchronization recovery capability may be still worse when the VLC encoded bit stream is transmitted over BSC.

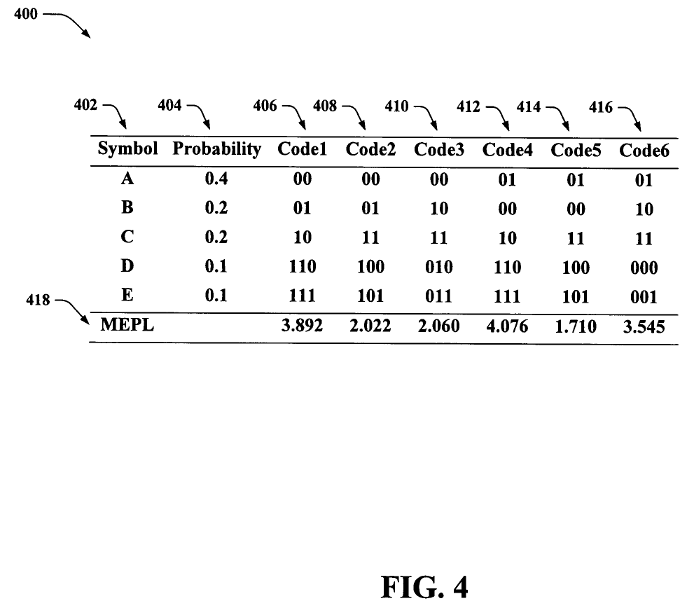

The efficacy of the above described embodiments can be verified by simulated results, as presented in non-limiting fashion in FIGS. 4-17. More particularly, accuracy of the theoretical results obtained above can be evaluated by extending three examples below: the five-character source, the English text source, and the Geometric source.

A. Five-Character Source

FIG. 4 illustrates a table 400 that includes example Huffman codes for the five-character source. There are sixteen distinct Huffman codes for five-character source, each of which has the same expected codeword length L_{X}(C)=2.2, as shown in table 400. Here, for the sake of simplicity, some of these Huffman codes, which have the same length vector L={0, 3, 2}, are considered as shown in table 400 (e.g., six distinct Huffman codes for the five-character source are included in table 400, . . . ). Any code in table 400 can be obtained via equivalent transformation from the other codes in the same table. As depicted, column 402 shows five symbols associated with the five-character source. Further, column 404 includes probabilities associated with each of the symbols in column 402. Moreover, columns 406-416 include respective, corresponding codewords for the symbols yielded from using each of the six distinct Huffman codes. Moreover, row 418 includes values for MEPL associated with each of the six codes.

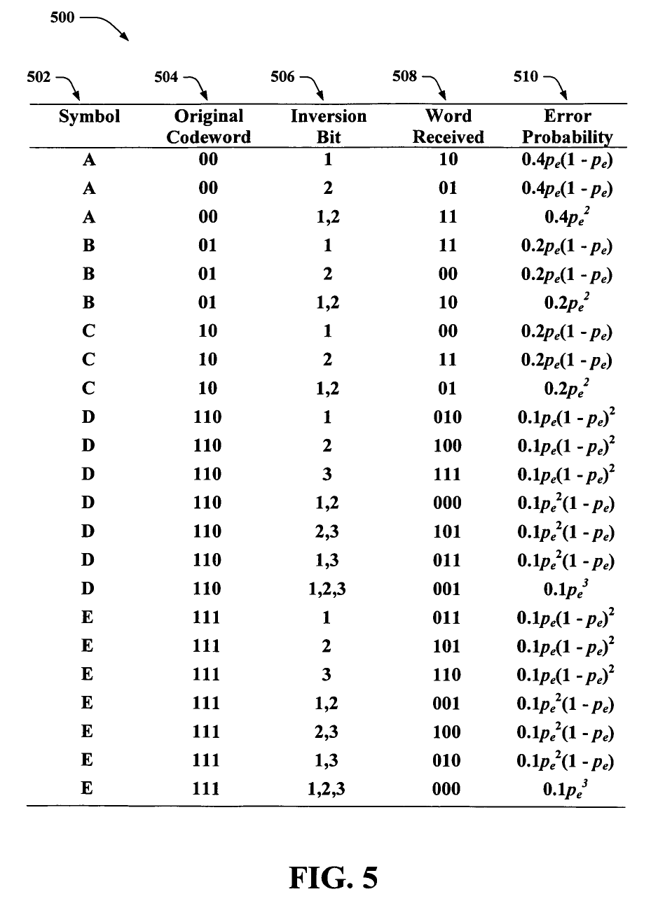

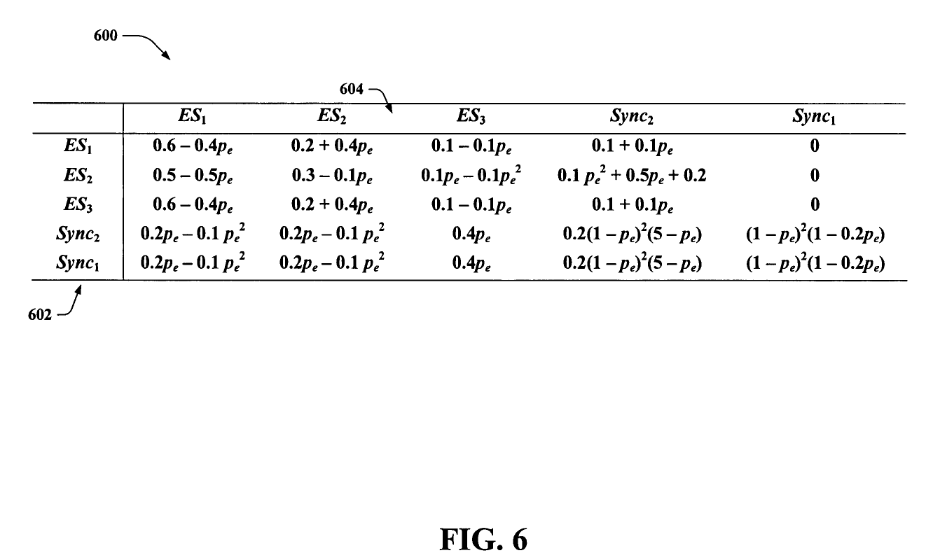

Referring to FIG. 5, illustrated is an example table 500 that represents reception error with bit inversion. Further, FIG. 6 illustrates an example state transition table 600. For Code 1, the possible bit inversions are given in table 500, in which all the error probabilities are expressed in terms of pₑ. Column 502 of table 500 includes symbols and column 504 includes original codewords that correspond to each of these symbols. Moreover, column 506 shows inversion bit(s) (e.g., that can result from transmission error, . . . ) and column 508 includes received words that are yielded as a result of the inversion bit(s). Moreover, column 510 includes error probabilities. The extended transition matrix, or equivalently, the state transition table, can then be shown in table 600 of FIG. 6. Table 600 depicts probabilities associated with transitioning from state i shown in column 602 to state j shown in row 604. By making use of Theorem 1, the value of MSER can be calculated.

$$μ = \frac{4 {p}_{e}^{6} - 5 {p}_{e}^{5} - 86 {p}_{e}^{4} + 42 {p}_{e}^{3} + 284 {p}_{e}^{2} + 471 {p}_{e}}{5 {p}_{e}^{4} - 20 {p}_{e}^{3} + 190 {p}_{e}^{2} + 480 {p}_{e} + 55} \qquad ( 31 )$$

Then, the MEPL per erroneous bit can be determined as follows:

$$γ = \frac{μ}{{p}_{e} {L}_{X} ( C )} = \frac{4 {p}_{e}^{5} - 5 {p}_{e}^{4} - 86 {p}_{e}^{3} + 42 {p}_{e}^{2} + 284 {p}_{e} + 471}{11 {p}_{e}^{4} - 44 {p}_{e}^{3} + 418 {p}_{e}^{2} + 1056 {p}_{e} + 121} \qquad ( 32 )$$

For the other five codes, in a similar fashion, the value of the corresponding MSER and MEPL per erroneous bit can be calculated.

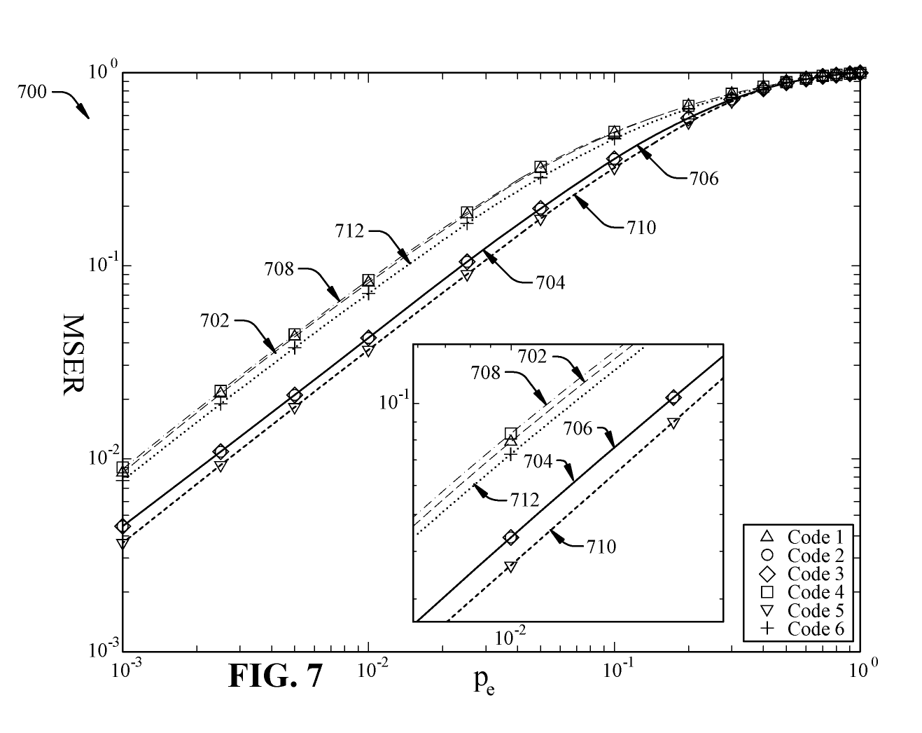

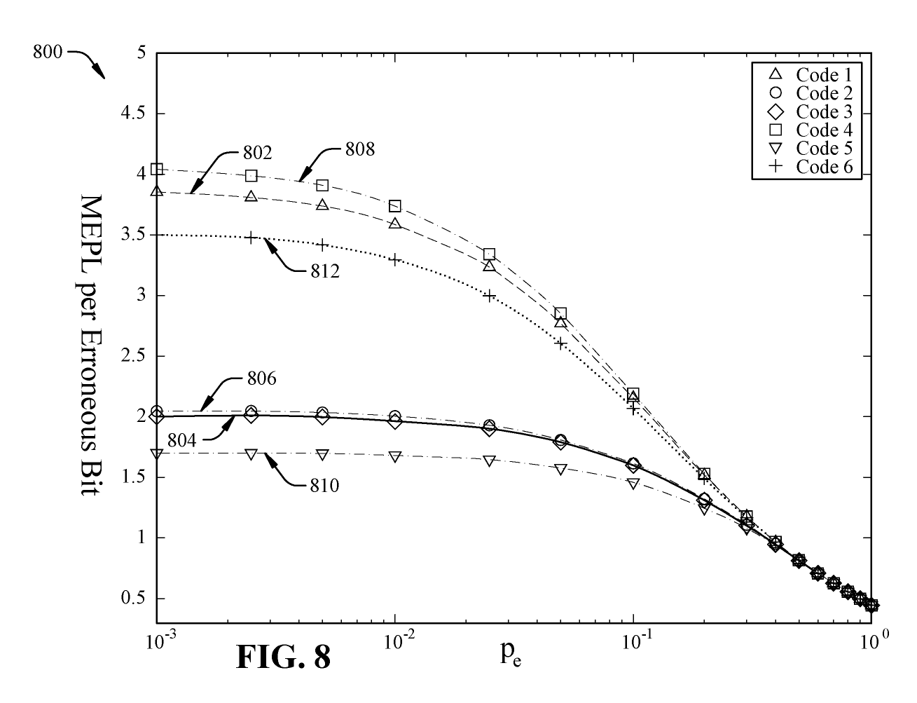

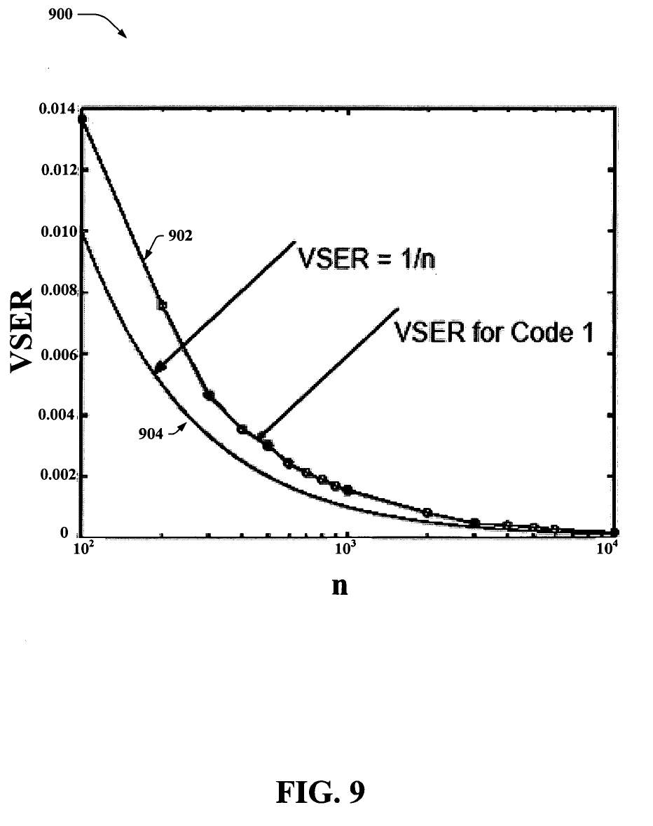

In FIGS. 7-9, comparisons between the theoretical results with the numerical simulations are presented for the five-character source. It is to be appreciated, however, that the claimed subject matter is not so limited. In FIG. 7, graph 700 illustrates MSER versus pₑ. In graph 700, curve 702 illustrates MSER as a function of pₑ for Code 1, curve 704 depicts MSER as a function of pₑ for Code 2, curve 706 illustrates MSER as a function of pₑ for Code 3, curve 708 represents MSER as a function of pₑ for Code 4, curve 710 depicts MSER as a function of pₑ for Code 5, and curve 712 illustrates MSER as a function of pₑ for Code 6. Graph 800 of FIG. 8 depicts MEPL per erroneous bit versus pₑ. In graph 800, curve 802 illustrates MEPL per erroneous bit versus pₑ for Code 1, curve 804 depicts MEPL per erroneous bit versus pₑ for Code 2, curve 806 illustrates MEPL per erroneous bit versus pₑ for Code 3, curve 808 depicts MEPL per erroneous bit versus pₑ for Code 4, curve 810 illustrates MEPL per erroneous bit versus pₑ for Code 5, and curve 812 depicts MEPL per erroneous bit versus pₑ for Code 6. Moreover, graph 900 of FIG. 9 illustrates VSER versus the input length n for Code 1 with pₑ=0.1. In graph 900, curve 902 illustrates VSER as a function of n for Code 1 and curve 904 shows VSER equaling 1/n as a function of n.

In FIG. 7 and FIG. 8, the lines (including the solid, dotted, dashed and dash-dot lines) are obtained from the theoretical formulas (for Code 1, the formulas are shown in Equations (31) and (32)), and the triangles, circles, diamonds, squares and plus signs are obtained through experiments averaging over 20,000 times with input symbol length n=10,000. It can be found that the simulations match the theoretical results very well. In addition, from FIG. 7, it can be seen that when pₑ is small, the MSER increases almost linearly with the increasing pₑ. From FIG. 8, it can be observed that when pₑ is small, the MEPL per erroneous bit gets close to the MEPL for single error case, as shown in the last row of table 4 of FIG. 4. These observations are all consistent with Theorem 3. In FIG. 9, the VSER is plotted as a function of pₑ. It can be seen that VSER tends to zero as n→∞, with decay rate nearly proportional to 1/n for large n. This coincides with the prediction stated in the remark of Theorem 2.

B. English Text

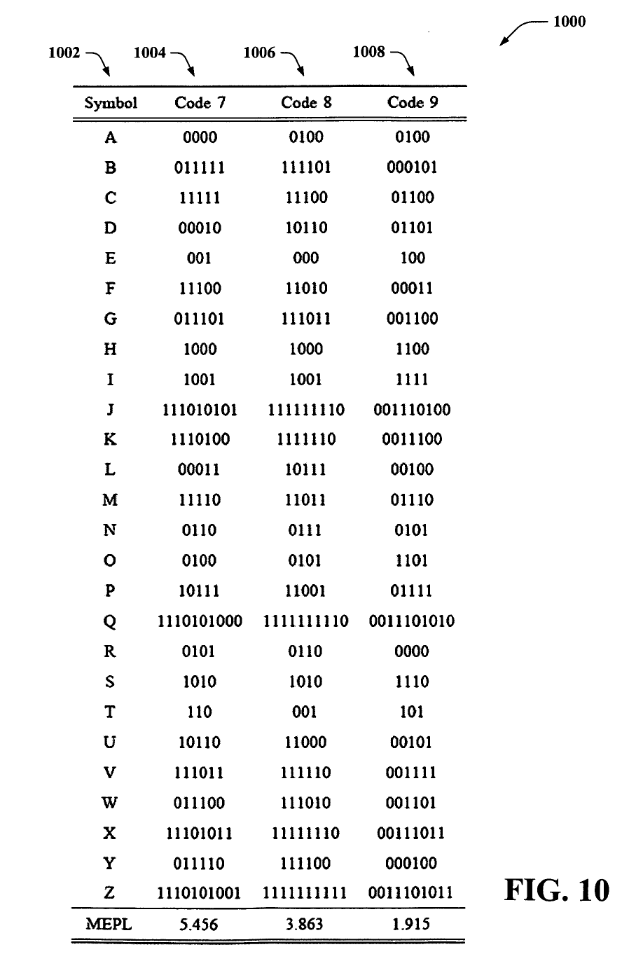

FIG. 10 illustrates a table 1000 that includes example Huffman codes for the English alphabet. Table 1000 includes four columns: column 1002 includes English text symbols, and columns 1004-1008 include codewords corresponding to each of the English text symbols for three disparate Huffman codes. Three Huffman codes for English text are shown in table 1000, including Code 7, Code 8, and Code 9, each of which can be obtained by performing equivalent transformation from the other codes in the same table. Since there are 26 symbols, the dimensionality of the extended transition matrix is 26×26, which makes the exact expression of MSER very complicated and too long to be shown. Here, to get the theoretical result of MSER, for every given pₑ, the extended transition matrix can be computed according to Equation (3), and Theorem 1 can be applied. It should be noted, however, that the complexity of computing the extended transition matrix grows exponentially with respect to the largest codeword length. Although some very unlikely error occurrences can be removed if their probabilities are below the computational precision, an efficient algorithm to compute the extended transition matrix for the codes with very large alphabet size can be used. A possible direction is to find an appropriate algebraic mapping between the code structure and the extended transition matrix, so that different entries in the matrix can be explicitly related. However, the problem of finding the polynomial time method for computing the extended transition matrix may be still open. This situation is similar to that of finding the code with minimum MEPL in single error case.

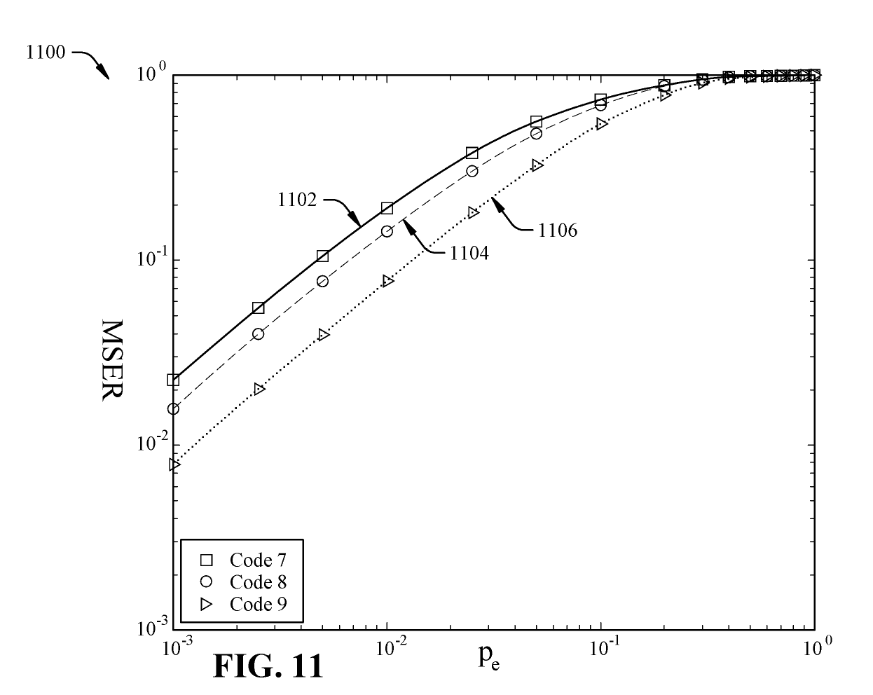

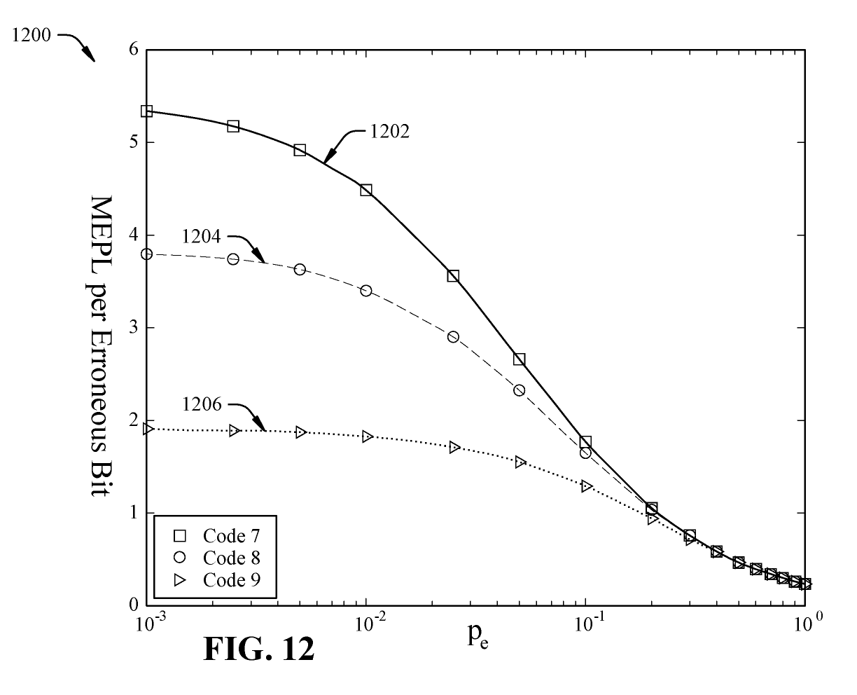

The comparisons of the theoretical results and the simulations are shown in FIGS. 11-12, where the lines are the theoretical results obtained as described above, and the triangles, circles and squares are obtained from simulations averaging over 20,000 times with input symbol length n=10,000. In graph 1100 of FIG. 11, MSER is shown versus pₑ for the English text example. In particular, curve 1102 illustrates MSER as a function of pₑ for Code 7, curve 1104 depicts MSER as a function of pₑ for Code 8, and curve 1106 illustrates MSER as a function of pₑ for Code 9. Moreover, in FIG. 12, graph 1200 depicts MEPL per erroneous bit versus pₑ. In general, similar observations hold, as for the case of five-character source. Graph 1200 includes curve 1202 depicting MEPL per erroneous bit as a function of pₑ for Code 7, curve 1204 illustrating MEPL per erroneous bit as a function of pₑ for Code 8, and curve 1206 depicting MEPL per erroneous bit as a function of pₑ for Code 9.

C. Geometric Source

When the probability mass function of a source with alphabet size N satisfies:

$${p}_{k} > {\sum }_{i = k + 2}^{N} {p}_{i} , for k = 1 , 2 , … , N - 3 \qquad ( 33 )$$

then the resulting Huffman code consists of N−2 codewords with lengths 1 through N−2, respectively, and two codewords of length N−1, such that the associated length vector is

$$( \underbrace{1 , 1 , … , 1}_{N - 2} , 2 ) .$$

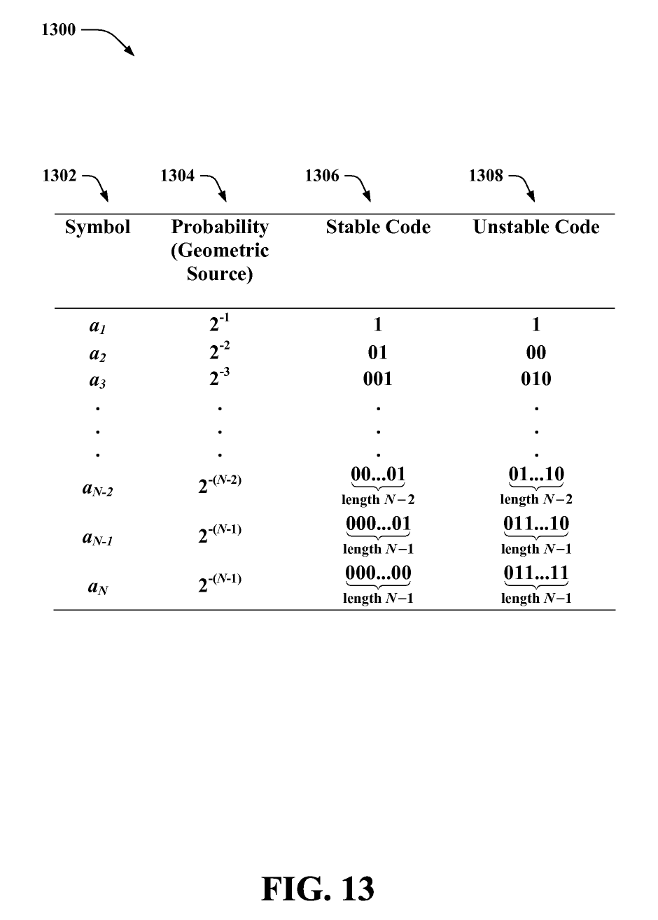

Two example sources are a Geometric source and a Fibonacci source. The stable code (e.g., which can also be referred to as comma code, . . . ) and the unstable code are two special Huffman codes for the source satisfying Equation (33), as shown in table 1300 of FIG. 13. Table 1300 includes symbols in column 1302, corresponding probabilities in column 1304, codewords for each of the symbols as set forth utilizing the stable code in column 1306, and codewords for each of the symbols as set forth employing the unstable code in column 1308.

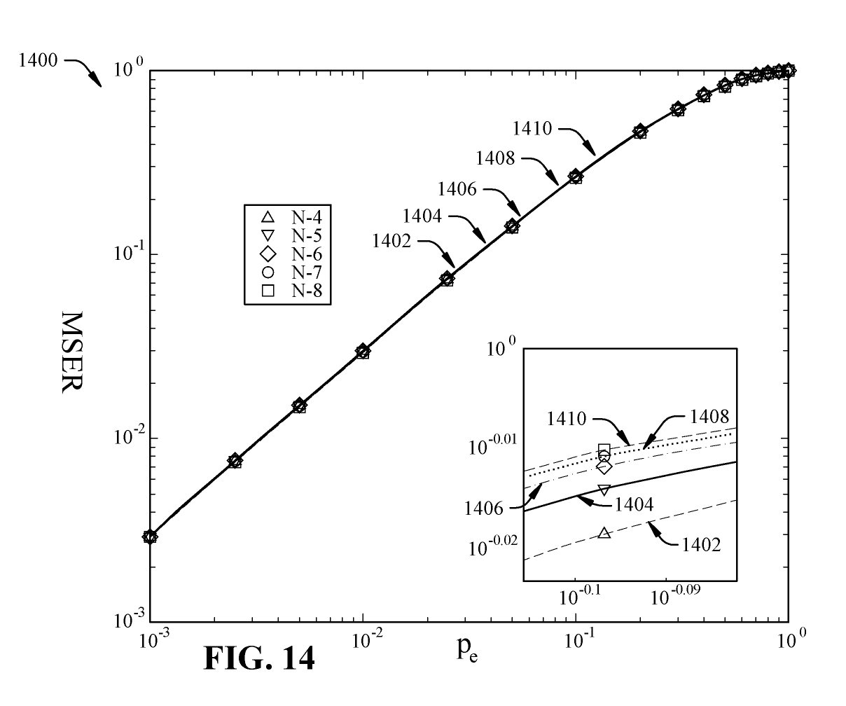

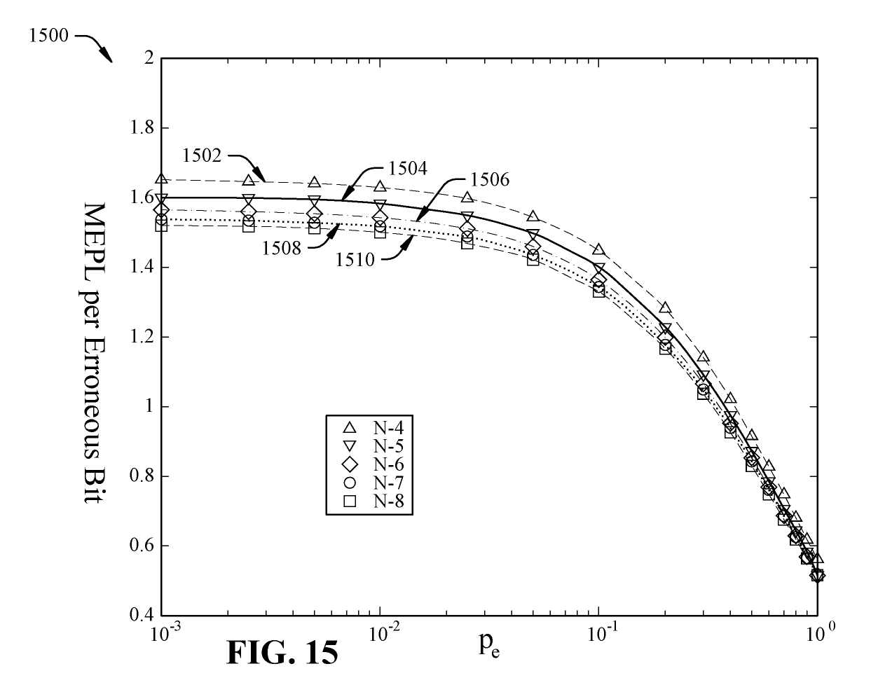

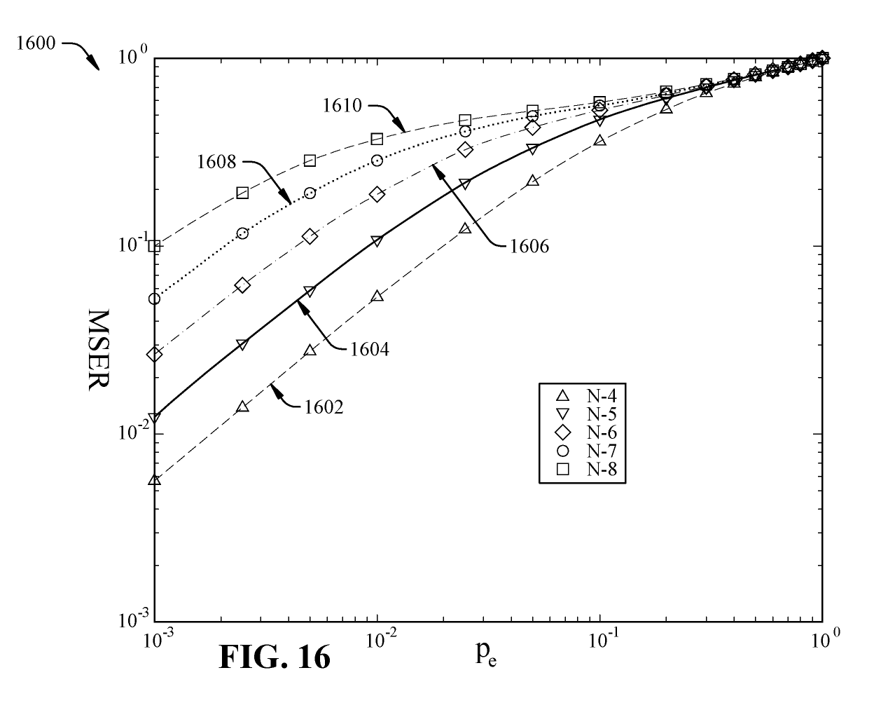

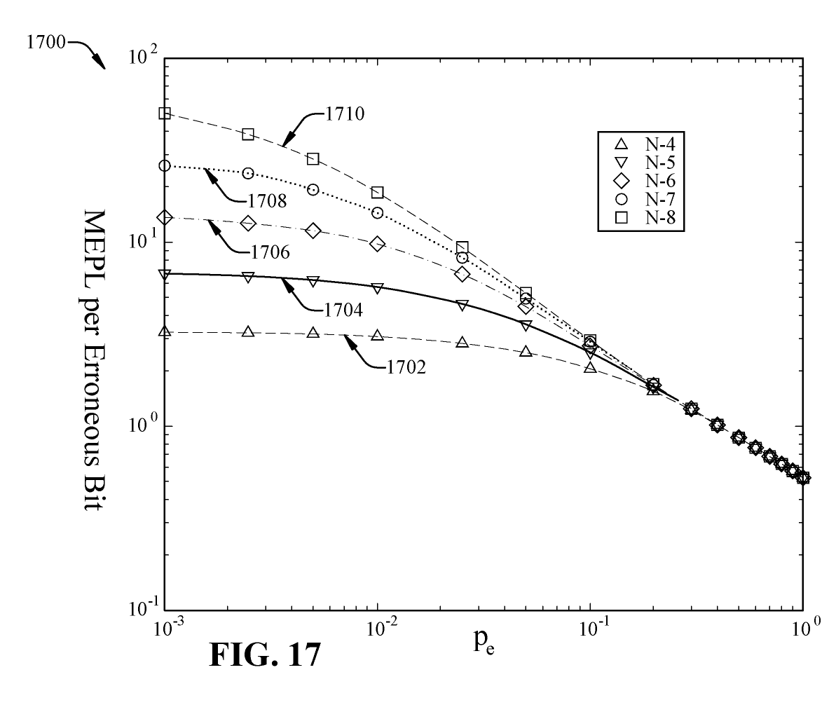

In FIGS. 14-17, taking the example of the Geometric source, the MSER and MEPL per erroneous bit are plotted for the stable code and unstable code with different alphabet sizes N. In FIG. 14, graph 1400 depicts MSER versus pₑ for stable code. Graph 1400 includes curve 1402 that depicts MSER as a function of pₑ for stable code with N=4, curve 1404 that illustrates MSER as a function of pₑ for stable code with N=5, curve 1406 that shows MSER as a function of pₑ for stable code with N=6, curve 1408 that depicts MSER as a function of pₑ for stable code with N=7, and curve 1410 that illustrates MSER as a function of pₑ for stable code with N=8. In FIG. 15, graph 1500 illustrates MEPL per erroneous bit versus pₑ for stable code. In graph 1500, curve 1502 illustrates MEPL per erroneous bit as a function of pₑ for stable code with N=4, curve 1504 depicts MEPL per erroneous bit as a function of pₑ for stable code with N=5, curve 1506 illustrates MEPL per erroneous bit as a function of pₑ for stable code with N=6, curve 1508 depicts MEPL per erroneous bit as a function of pₑ for stable code with N=7, and curve 1510 shows MEPL per erroneous bit as a function of pₑ for stable code with N=8. Further, in FIG. 16, graph 1600 shows MSER versus pₑ for unstable code. Graph 1600 includes curves 1602-1610. Curve 1602 depicts MSER as a function of pₑ for unstable code with N=4, curve 1604 illustrates MSER as a function of pₑ for unstable code with N=5, curve 1606 shows MSER as a function of pₑ for unstable code with N=6, curve 1608 illustrates MSER as a function of pₑ for unstable code with N=7, and curve 1610 depicts MSER as a function of pₑ for unstable code with N=8. Moreover, in FIG. 17, graph 1700 depicts MEPL per erroneous bit versus pₑ for unstable code. In graph 1700, curve 1702 illustrates MEPL per erroneous bit as a function of pₑ for unstable code with N=4, curve 1704 depicts MEPL per erroneous bit as a function of pₑ for unstable code with N=5, curve 1706 illustrates MEPL per erroneous bit as a function of pₑ for unstable code with N=6, curve 1708 shows MEPL per erroneous bit as a function of pₑ for unstable code with N=7, and curve 1710 depicts MEPL per erroneous bit as a function of pₑ for unstable code with N=8. For stable code, the MEPLs corresponding to N=4, N=5, N=6, N=7, and N=8, respectively, are 1.653, 1.604, 1.566, 1.540, and 1.534. Moreover, for unstable code, the MEPLs corresponding to N=4, N=5, N=6, N=7, and N=8, respectively, are 3.2857, 6.8667, 14.419, 29.952, and 61.472. Besides the similar observations as shown in the previous two examples, it can be found, from FIGS. 14 and 15 that the stable code with N=4 has the smallest MSER, while it has the largest MEPL. This confirms the previous statement that when comparing the synchronization recovery capability of two VLCs, smaller MEPL does not necessarily guarantee smaller MSER, unless their expected codeword lengths are equal.

In accordance with various aspects, the analysis of synchronization recovery of VLC has been extended to the BSC scenario. Hence, a simple expression, for MSER has been derived. In addition, VSER can be shown to equal zero when the input symbol length n→∞. Particularly, as demonstrated, for large n, the decay rate of VSER is almost inversely proportional to n. Furthermore, a relationship between MEPL for single error case and MSER has been established by proving that when the crossover probability pₑ tends to zero, MEPL becomes a scaled value of MSER. Moreover, simulations using three examples have also been presented to verify the validity of the theoretical results.

According to the following, various aspects of the subject disclosure are present in conjunction with proof of a conjecture on error recovery for variable length codes. The conjecture can be that, for a Geometric source, the stable code has the best error recovery performance for the case of bit inversion among all Huffman codes for this source, while the unstable code has the worst error recovery performance. This conjecture can be further extended to sources with certain probability mass function. Below, correctness of this conjecture is proven.

Variable length codes (VLCs) have found widespread use for efficient encoding of symbols with unequal probabilities in many practical situations. However, a major drawback of VLC is that decoder synchronization is required for correct decoding, and a loss of synchronization often leads to error propagation. To reduce the error propagation effect, various techniques can be used such as the error-resilient entropy coding (EREC), reversible variable length codes (RVLC), variable-to-fixed length codes, multiplexed codes, and self-synchronizing codes. On the other hand, the improvement may also come from the richness of the structures of VLC, namely, a code with good error recovery performance among all equivalent codes can be selected, without loss of coding efficiency. To achieve this goal, precise measures can be used to compare the error recovery performance. For instance, a state model to calculate the statistical moments of error span has been developed. Further, the model can be simplified such that the mean and the variance of error span can be obtained via the inversion and multiplication of dimension n−1 square matrices of constants. Moreover, a simple expression for the mean error propagation length (MEPL, e.g., the mean value of error span) and the variance of error propagation length (VEPL, e.g., the variance of error span) can be employed by using the summation of semi-infinite series. Further, a formula to compute MEPL for a binary symmetric channel (BSC) model with given crossover probability can be utilized.

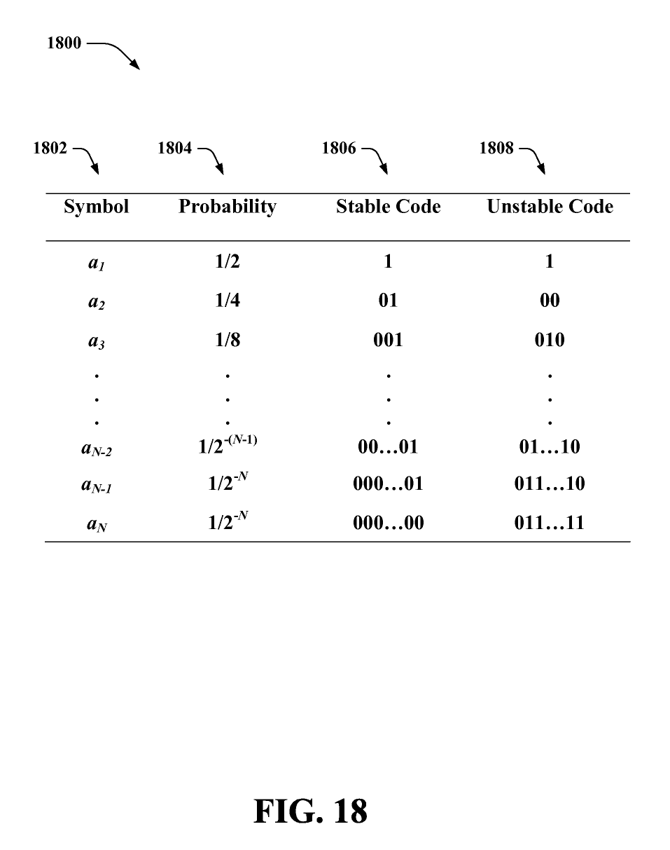

Nevertheless, to find the best VLC in terms of the error recovery performance, among all the codes which have the same coding efficiency, is still a very difficult task, especially when the alphabet size is large. For a particular source, such as a Geometric source, it may be conjectured that the stable code has the best error recovery performance for the case of bit inversion among all Huffman codes for this source, while the unstable code has the worst error recovery performance. The Geometric source and the stable/unstable code are shown in table 1800 of FIG. 18. Column 1802 of table 1800 includes symbols, column 1804 includes probabilities corresponding to the symbols shown in column 1802, and columns 1806 and 1808 include codewords corresponding to each of the symbols as set forth per stable code and unstable code, respectively. Further, this conjecture can be extended to sources with probability mass function (PMF) satisfying the following:

$${p}_{k} > {\sum }_{i = k + 2}^{N} {p}_{i} , for k = 1 , 2 , … , N - 3 \qquad ( 34 )$$

where pᵢ is the occurrence probability of the ith symbol and N is the alphabet size. The resulting Huffman code consists of N−2 codewords with lengths 1 through N−2, respectively, and two codewords of length N−1. Since the stable code has the maximum suffix condition, and the unstable code has the minimum suffix condition, the aforementioned conjecture is helpful to gain some insight into the effectiveness of suffix condition in finding an error-resilient code.

The following Theorem, which is a formal statement of the conjecture, is proven herein. Unless otherwise stated, in the sequel, the assumption that the transmission fault process is a random single bit inversion is followed.

Theorem 4: Consider a source with PMF satisfying Equation (34).

I) Let μₛ and μₙₛ, respectively, stand for the MEPL for the stable code and the non-stable code. Then,

μ_{s<μ}ₙₛ (35)

In other words, the best error recovery performance for the case of bit inversion among all Huffman codes for this source, results from the stable code configuration.

II) Let μᵤₛ and μₙᵤₛ, respectively, stand for the MEPL for the unstable code and non-unstable code. Then,

μ_{us>μ}ₙᵤₛ (36)

In other words, the worst error recovery performance for the case of bit inversion among all Huffman codes for this source, results from the unstable code configuration.

Due to symmetry, without loss of generality, it is assumed that the codeword of a₁ is 1 for Huffman codes. Hence, the stable code and the unstable code are respectively unique. In addition, when considering the stable code, other Huffman codes can be defined as the non-stable codes. Further, when considering the unstable code, other Huffman codes can be defined as the non-unstable codes. For sake of simplicity, non-stable code and non-unstable code are used to denote arbitrary non-stable code and non-unstable code.

Let the source alphabet be A={a₁, a₂, a_{N}}, and let the PMF of this source be p(a₁), p(a₂), . . . ,p(a_{N}). The source is encoded by a binary prefix code C={c₁, c₂, . . . , c_{N}}, where cᵢ is the codeword of aᵢ. Given a code C, Lₘₐₓ can be defined as Lₘₐₓ=max {l(c)|c εC}, where l(c) is the length of c, and length vector L=(L₁, L₂, . . . , L_{L}_{ₘₐₓ}), where Lᵢ is the number of codewords with length i.

For two matrices A={aᵢⱼ}_{m×n}, and B={bᵢⱼ}_{m×n}, if aᵢⱼ≧bᵢⱼ for all i,j, then A≧B. If, in fact, aᵢⱼ>bᵢⱼ for all i,j, then A>B.

A square non-negative matrix T is said to be primitive if there exists a positive integer k such that T^{k}>0, where 0 denotes the matrix with all zero entries.

For a square matrix T={tᵢⱼ}_{n×n}, suppose that there exists a real or complex number λ such that λu′=u′T, λv=Tv, for some vector u and v, where “′” stands for transpose. Then λ is called an eigenvalue of T, and u (v, respectively) is called a left (right) eigenvector of T. The largest eigenvalue λ in magnitude of a primitive matrix is called the Perron-Frobenius(PF) eigenvalue, and according to the Perron-Frobenius Theorem, λ is a real positive number. The associated left and right eigenvectors u and v, respectively, are called PF left and PF right eigenvectors if u and v are positive componentwise and u′1ₙ=u′v=1, where

$${1}_{n} = {( \underbrace{1 , 1 , … , 1}_{n} )}^{′} .$$

Proof of Theorem 4: The error recovery of VLC can be modeled as a set of states and state transitions governed by source probabilities and code structure. The set of states can be defined as:

S={I, ES₁, ES₂, . . . , ES_{M}, Syn} (37)

where M=N−2 is the number of internal nodes of the binary tree corresponding to the VLC, I denotes the initial steady state, ESᵢ denotes the ith error state which matches the ith internal node, and Syn is the synchronization state. Every element in S is associated with a string of bits, specifically, I and Syn are associated with an empty string, and ESᵢ is associated with the bit representation of the ith internal node.

When the PMF of a source satisfies Equation (34), the length vectors of all the Huffman codes for this source are

$$( \underbrace{1 , 1 , … , 1}_{N - 2} , 2 ) ,$$

where N is the alphabet size.
Hence, an additional ending vector E=(E₁, E₂, . . . , E_{N-2}) can be defined to uniquely determine a Huffman code, where Eᵢ is the ending bit of the codeword with length i (1≦i≦N−2). For example, E=(1, 0, 0, 1) corresponds to the code {1, 00, 010, 0111, 01101, 0100}. To be consistent with the above assumption, let E₁=1 for all Huffman codes. The stable code and the unstable code, respectively, correspond to E=(1, 1, . . . , 1) and E=(1, 0, . . . , 0).

For the proof of Theorem 4, the following Lemmas are provided.

Lemma 6: Consider a source with PMF satisfying Equation (34). Let \vec{p}ₛ=(pₛ(1), . . . , pₛ(N−2)), where pₛ(i) is the transition probability from initial state I to ESᵢ for the stable code, and \vec{p}ₙₛ is defined similarly for non-stable code of this source. For instance, the transition probability from I to ESᵢ can be stated as the probability that the codeword including a bit error ends up with ESᵢ after parsing. Then,

\vec{p}ₛ1ₙ₋₂<\vec{p}ₙₛ1_{N-2} (38)

Proof: Let the ending vector be E=(E₁, E₂, . . . , E_{N-2}). A general form of all Huffman codes can be written as:

C={E₁, Ē₁E₂, . . . , Ē₁Ē₂. . . Ē_{N-3}E_{N-2}, Ē₁Ē₂. . . Ē_{N-2}1, Ē₁Ē₂. . . Ē_{N-2}0} (39)

where ‘Ēⱼ’ is the bit inversion of Eⱼ.

When a bit error occurs in a codeword cᵢ of the stable code, there are three possible cases: (1) for 1≦i≦N−2, the error occurring at the first i−1 bits leads to synchronization state, while the error occurring at the last bit results in an error state; (2) for i=N−1, the error occurring at any location leads to synchronization state; (3) for i=N, the error occurring at the last bit leads to synchronization state, while all the other error patterns result in error states. Hence, for the stable code, the transition probability from I to Syn is as follows:

$$\begin{matrix}{Pr}_{s} ( I \to Syn ) = {\sum }_{i = 1}^{N} {Pr}_{s} ( I \to Syn \vert {a}_{i} ) p ( {a}_{i} ) \\ = \overbrace{{\sum }_{i = 1}^{N - 2} [ \frac{p ( {a}_{1} )}{{L}_{X} ( C )} ( i - 1 ) ]}^{case ( 1 )} + \overbrace{\frac{p ( {a}_{N - 1} )}{{L}_{X} ( C )} ( N - 1 )}^{case ( 2 )} + \\ \frac{\overbrace{p ( {a}_{N} )}^{case ( 3 )}}{{L}_{X} ( C )}\end{matrix} \qquad ( 40 )$$

where

$${L}_{X} ( C ) = {\sum }_{i = 1}^{N} p ( {a}_{i} ) l ( {c}_{i} )$$

is the expected codeword length.

Notice that, for both the stable code and the non-stable code, when the bit error occurs at the last bit of cᵢ, 1≦i≦N−2, the state after parsing is an error state. Otherwise the prefix condition will be violated or there will be more than one codewords with length i. As the stable code causes all the other error patterns to end up with synchronization state, it maximizes

$${\sum }_{i = 1}^{N - 2} Pr ( I \to Syn \vert {a}_{i} ) p ( {a}_{i} ) .$$

It is easy to verify that this maximum value can only be achieved by the stable code configuration.

The last two codewords c_{N-1}=Ē₁Ē₂ . . . Ē_{N-2}1 and c_{N}=Ē₁Ē₂ . . . Ē_{N-2}0 can further be considered. Without loss of generality and for simplicity, in the sequel, it can be assumed that p(a_{N-1})≧p(a_{N}). The two example sources, Geometric source and the Fibonacci source, are special cases where p(a_{N-1})=p(a_{N}). Suppose there is a bit error at Ēᵢ, 1≦i≦N−2, as Ē₁Ē₂. . . Ēᵢ₋₁Ēᵢ is a valid codeword, the state after parsing the corrupted version of c_{N-1} and c_{N} are, respectively, the same as that of the bit string s₁=Ēᵢ₊₁Ēᵢ₊₂. . . Ēhd N−21 and s₀=Ēᵢ₊₁Ēᵢ₊₂. . . Ē_{N-2}0. Since the length vector is

$$( \underbrace{1 , 1 , … , 1}_{N - 2} , 2 ) ,$$

the two children of any internal nodes in the binary tree, except the one giving rise to cₙ₋₁ and c_{N}, consist of one leaf node and one internal node. Hence, for s₁ and s₀, one ends up with synchronization state after parsing, while the other one results in an error state. This implies that, for both the stable code and the non-stable code,

$${\sum }_{i = N - 1}^{N} Pr ( I \to Syn \vert {a}_{i} ) p ( {a}_{i} ) = \frac{p ( {a}_{N - 1} )}{{L}_{X} ( C )} m + \frac{p ( {a}_{N} )}{{L}_{X} ( C )} n \qquad ( 41 )$$

for some integers 1≦m, n≦N−1 satisfying m+n=N. Since p(a_{N-1})≧p(a_{N}), clearly, the choice of m=N−1 and n=1, which is achieved by the stable code configuration, maximizes Equation (41).

Therefore, combining the above cases, it can be determined that the maximum value of Pr(I→Syn) can, and only can, be achieved by the stable code. As \vec{p}_{s/ns}1_{N-2}=1−Pr_{s/ns}(I→S), this immediately completes the proof.

Corollary 1: Consider a source with PMF satisfying Equation (34). Let \vec{p}ᵤₛ=(pᵤₛ(1), . . . pᵤₛ(N−2)), where pᵤₛ(i) is the transition probability from initial state I to ESᵢ for the unstable code, and \vec{p}ₙᵤₛ is defined similarly for non-unstable code of this source. Then,

\vec{p}ᵤₛ1_{N-2}>\vec{p}ₙᵤₛ1_{N-2} (42)

Proof: The proof is similar to that of Lemma 6.

Lemma 7: Consider a Huffman code for a source with PMF satisfying Equation (34). Let Q={qᵢⱼ}_{M×M} be the error state transition matrix for this Huffman code, where qᵢⱼ denotes the transition probability from ESᵢ to ESⱼ, and M=N−2. Then,

$${lim}_{k \to ∞} {Q}^{k} = 0 \qquad ( 43 )$$

Proof: From the proof of Lemma 6, it can be evident that the transition probability from any error state to synchronization state is non-zero, as after receiving one of c_{N-1} and c_{N}, the state after parsing is synchronization state. Hence, for the error state transition matrix, the following can be yielded:

$$0 \leq {q}_{ij} < 1 and {\sum }_{j = 1}^{M} {q}_{ij} < 1 \qquad ( 44 )$$

Define another matrix \hat{Q}=\hat{q}ᵢⱼ}_{M×M}, where

$${\hat{q}}_{ij} = \{ \begin{matrix}{q}_{ij} & if {q}_{ij} > 0 \\ {q}_{ij} + {ɛ}_{ij} & if {q}_{ij} = 0\end{matrix} \qquad ( 45 )$$

where εᵢⱼ>0 is sufficiently close to zero such that

$${\sum }_{j = 1}^{M} {\hat{q}}_{ij} < 1.$$

### Thus,

0≦Q≦\hat{Q} (46)

Notice that \hat{Q} is a primitive matrix, and according to Corollary 1 of the Perron-Frobenius Theorem, the following can be obtained:

$${min}_{i} {\sum }_{j = 1}^{M} {\hat{q}}_{ij} \leq λ \leq {max}_{i} {\sum }_{j = 1}^{M} {\hat{q}}_{ij} \qquad ( 47 )$$

where λ is the PF eigenvalue associated with \hat{Q}, and the equality on either side implying equality throughout. Therefore,

0<λ<1 (48)

which follows that

$$0 \leq {lim}_{k \to ∞} {Q}^{k} \leq {lim}_{k \to ∞} {\hat{Q}}^{k} {=}^{( a )} {lim}_{k \to ∞} {λ}^{k} {vu}^{′} = 0 \qquad ( 49 )$$

where u and v are, respectively, the PF left and PF right eigenvector associated with \hat{Q}. Thus, lim_{k→∞}Q^{k}=0, and this completes the proof

Remark: It can be shown that if a non-negative matrix T={tᵢⱼ}_{M×M} is satisfied

$${\sum }_{j = 1}^{M} {t}_{ij} \leq 1 ,$$

and the equality does not hold for all i, then lim_{k→∞}T^{k}=0. However, this is not true for all cases. The following provides a counter example:

$$T = ( \begin{matrix}0.2 & 0.8 & 0 \\ 0.2 & 0.8 & 0 \\ 0.1 & 0.6 & 0.1\end{matrix} ) \qquad ( 50 )$$

in which the following is obtained

$${T}^{∞} = ( \begin{matrix}0.2 & 0.8 & 0 \\ 0.2 & 0.8 & 0 \\ 0.1556 & 0.6222 & 0\end{matrix} ) \qquad ( 51 )$$

In fact, the condition that T is a primitive matrix should be imposed. Otherwise the two conditions

$${\sum }_{j = 1}^{M} {t}_{ij} \leq 1 ,$$

and the equality does not hold for all i, cannot guarantee that the amplitude of the maximum eigenvalue is strictly less than one. The proof that T is primitive will be reported elsewhere.

Lemma 8: Consider a Huffman code for a source with PMF satisfying Equation (34). Let T={tᵢⱼ}_{M×M} be the error state transition matrix for this Huffman code, which satisfies

$${\sum }_{j = 1}^{M} {t}_{ij} \geq β ,$$

for all 1≦i≦M, where M=N−2 and 0<β<1.

### Assume

$${( I - T )}^{- 1} = R = ( \begin{matrix}{r}_{11} & {r}_{12} & ⋯ & {r}_{1 M} \\ {r}_{21} & {r}_{22} & ⋯ & {r}_{2 M} \\ ⋮ & ⋮ & ⋰ & ⋮ \\ {r}_{M 1} & {r}_{M 2} & ⋯ & {r}_{MM}\end{matrix} )$$

Then,

$${\sum }_{j = 1}^{M} {r}_{ij} \geq \frac{1}{1 - β} , \\ for all 1 \leq i \leq M \qquad ( 52 )$$

where the equality holds when

$${\sum }_{j = 1}^{M} {t}_{ij} = β ,$$

for all i.

Proof: Lemma 7 provides the following:

$${lim}_{k \to ∞} {T}^{k} = 0 \qquad ( 53 )$$

Hence, (I−T)⁻¹ exists and

$$R = {( I - T )}^{- 1} = {\sum }_{k = 0}^{∞} {T}^{k} \qquad ( 54 )$$

Since T is a non-negative matrix, then

rᵢⱼ≧0, for all 1≦i,j≦M (55)

As R is the inverse of I−T. e.g.,

$$( \begin{matrix}{r}_{11} & {r}_{12} & ⋯ & {r}_{1 M} \\ {r}_{21} & {r}_{22} & ⋯ & {r}_{2 M} \\ ⋮ & ⋮ & ⋰ & ⋮ \\ {r}_{M 1} & {r}_{M 2} & ⋯ & {r}_{MM}\end{matrix} ) ( \begin{matrix}1 - {t}_{11} & - {t}_{12} & ⋯ & - {t}_{1 M} \\ - {t}_{21} & 1 - {t}_{22} & ⋯ & - {t}_{2 M} \\ ⋮ & ⋮ & ⋰ & ⋮ \\ - {t}_{M 1} & - {t}_{M 2} & ⋯ & 1 - {t}_{MM}\end{matrix} ) = I \qquad ( 56 )$$

it follows from the first row that

$$\{ \begin{matrix}{r}_{11} = {r}_{11} {t}_{11} + {r}_{12} {t}_{21} + … + {r}_{1 M} {t}_{M 1} + 1 \\ {r}_{12} = {r}_{11} {t}_{12} + {r}_{12} {t}_{22} + … + {r}_{1 M} {t}_{M 2} \\ ⋮ \\ {r}_{1 M} = {r}_{11} {t}_{1 M} + {r}_{12} {t}_{2 M} + … + {r}_{1 M} {t}_{MM}\end{matrix} \qquad ( 57 )$$

Adding these equations together, the following is obtained:

$${\sum }_{j = 1}^{M} {r}_{1 j} = {r}_{11} {\sum }_{j = 1}^{M} {t}_{1 j} + {r}_{12} {\sum }_{j = 1}^{M} {t}_{2 j} + … + {r}_{1 M} {\sum }_{j = 1}^{M} {t}_{Mj} + 1 \geq β {\sum }_{j = 1}^{M} {r}_{1 j} + 1 \qquad ( 58 )$$

Thus,

$${\sum }_{j = 1}^{M} {r}_{1 j} \geq \frac{1}{1 - β} \qquad ( 59 )$$

where the equality holds when

$${\sum }_{j = 1}^{M} {t}_{ij} = β ,$$

for all i.

In a similar way, it can be proven that

$${\sum }_{j = 1}^{M} {r}_{ij} \geq \frac{1}{1 - β} \qquad ( 60 )$$

for all 1≦i≦M, and the equality holds when

$${\sum }_{j = 1}^{M} {t}_{ij} = β ,$$

for all i. This completes the proof.

Corollary 2: Consider a Huffman code for a source with PMF satisfying Equation (34). Let T={tᵢⱼ}_{M×M} be the error state transition matrix for this Huffman code, which satisfies

$${\sum }_{j = 1}^{M} {t}_{ij} \leq 1 - β ,$$

for all 1≦i≦M, where M=N−2 and 0<β<1. Assume R=(I−T)⁻¹. Then,

$${\sum }_{j = 1}^{M} {r}_{ij} \leq \frac{1}{β} , \\ for all \\ 1 \leq i \leq M \qquad ( 61 )$$

where the equality holds when

$${\sum }_{j = 1}^{M} {t}_{ij} = 1 - β ,$$

for all i.

Proof: The proof is similar to that of Lemma 8.

Proof of Part I of Theorem 4: For the stable code, it is not difficult to verify that

$$Pr ( {ES}_{i} \to {ES}_{j} ) = \{ \begin{matrix}p ( {a}_{N} ) & if i = j \\ 0 & if i \neq j\end{matrix} \qquad ( 62 )$$

Hence, in matrix form, the error state transition matrix is

$$Q = {( \begin{matrix}p ( {a}_{N} ) & 0 & … & 0 \\ 0 & p ( {a}_{N} ) & … & 0 \\ ⋮ & ⋮ & ⋰ & ⋮ \\ 0 & 0 & … & p ( {a}_{N} )\end{matrix} )}_{M \times M} \qquad ( 63 )$$

where M=N−2.

For non-stable code, it is not difficult to find that there exists at least one pair of (i,j), 1≦i,j≦N−2, such that from an error state ESᵢ, after receiving cⱼ, the state after parsing is an error state. Otherwise, the non-stable condition will be violated. In addition, from any error state, after receiving one of c_{N-1} and c_{N}, the state after parsing is an error state. Thus, the error state transition matrix for non-stable code can be written as:

$$T = ( \begin{matrix}{t}_{11} & {t}_{12} & … & {t}_{1 M} \\ {t}_{21} & {t}_{22} & … & {t}_{2 M} \\ ⋮ & ⋮ & ⋰ & ⋮ \\ {t}_{M 1} & {t}_{M 2} & … & {t}_{MM}\end{matrix} ) \qquad ( 64 )$$

where

$$p ( {a}_{N} ) \leq {\sum }_{j = 1}^{N - 2} {t}_{ij} < 1 ,$$

but the equality does not hold for all i.

Further, the MEPL for the stable code and the non-stable code can be, respectively,

$$\begin{matrix}\begin{matrix}{μ}_{s} = 1 + {{\vec{p}}_{ns} ( I - Q )}^{- 1} {1}_{N - 2} \\ = 1 + \frac{1}{1 - p ( {a}_{N} )} {\vec{ρ}}_{s} {1}_{N - 2}\end{matrix} \\ and & ( 65 ) \\ {μ}_{ns} = 1 + {{\vec{ρ}}_{ns} ( I - T )}^{- 1} {1}_{N - 2} & ( 66 )\end{matrix}$$

where \vec{p}ₛ and \vec{p}ₙₛ are defined in Lemma 6.

Then,

$$\begin{matrix}{μ}_{ns} = 1 + {{\vec{p}}_{ns} ( I - T )}^{- 1} {1}_{N - 2} {>}^{( a )} \\ 1 + \frac{1}{1 - p ( {a}_{N} )} {\vec{p}}_{ns} {1}_{N - 2} {>}^{( b )} \\ 1 + \frac{1}{1 - p ( {a}_{N} )} {\vec{p}}_{s} {1}_{N - 2} \\ = {μ}_{s}\end{matrix} \qquad ( 67 )$$

where (a) follows from Lemma 8, and (b) follows from Lemma 6. This completes the proof.

Proof of Part II of Theorem 4: It is not difficult to find that, for the unstable code, the error state transition matrix is:

$$Q = ( \begin{matrix}{q}_{11} & {q}_{12} & … & {q}_{1 M} \\ {q}_{21} & {q}_{22} & … & {q}_{2 M} \\ ⋮ & ⋮ & ⋰ & ⋮ \\ {q}_{M 1} & {q}_{M 2} & … & {q}_{MM}\end{matrix} ) \qquad ( 68 )$$

where M=N−2, and

$${\sum }_{j = 1}^{N - 2} {q}_{ij} = 1 - p ( {a}_{N} ) , \\ for all \\ 1 \leq i \leq N - 2 \qquad ( 69 )$$

For non-unstable code, the error state transition matrix is:

$$T = ( \begin{matrix}{t}_{11} & {t}_{12} & … & {t}_{1 M} \\ {t}_{21} & {t}_{22} & … & {t}_{2 M} \\ ⋮ & ⋮ & ⋰ & ⋮ \\ {t}_{M 1} & {t}_{M 2} & … & {t}_{MM}\end{matrix} ) \qquad ( 70 )$$

where

$${\sum }_{j = 1}^{N - 2} {t}_{ij} \leq 1 - p ( {a}_{N} ) ,$$

but the equality does not hold for all i. Hence,

$$\begin{matrix}{μ}_{nus} = 1 + {{\vec{p}}_{nus} ( I - T )}^{- 1} {1}_{N - 2} {<}^{( a )} 1 + \\ \frac{1}{p ( {a}_{N} )} {\vec{p}}_{nus} {1}_{N - 2} {<}^{( b )} 1 + \frac{1}{p ( {a}_{N} )} {\vec{p}}_{us} {1}_{N - 2} \\ = 1 + {{\vec{p}}_{us} ( I - Q )}^{- 1} {1}_{N - 2} \\ = {μ}_{us}\end{matrix} \qquad ( 71 )$$

where (a) follows from Corollary 2, and (b) follows from Corollary 1. This completes the proof.

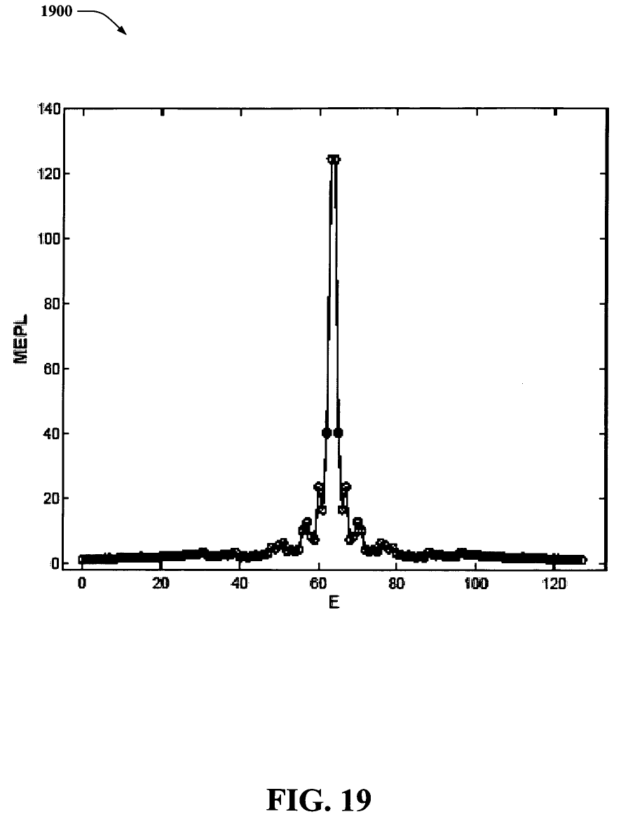

For Geometric source, the MEPL with respect to the decimal representation of the ending vector E (e.g., the decimal representation of E={1, 0, 1, 0} is 10) can be visualized in FIG. 19. FIG. 19 includes a graph 1900 illustrating MEPL versus the decimal representation of ending vector E. Further, for graph 1900, the largest codeword length Lₘₐₓ=8.

In fact, the advantage of the stable code configuration can also be interpreted as follows. Suppose the ending vector is E=(E₁=1, E₂, . . . , E_{N-2}), and hence, the code C={E₁, Ē₁E₂, . . . }. Consider a more general case that the bit stream produced by this VLC is transmitted over a BSC. The codeword Ē₁E₂ can be corrupted into three different versions, Ē₁Ē_{2,} E₁E₂ and E₁Ē₂. When the one-bit inversion error occurs at the last bit (e.g., Ē₁Ē₂), it must result in an error state, irrespective of the value of E₂. If E₂=E₁(E₂≠E₁, respectively), the state after parsing E₁E₂ is synchronization state (an error state), while for E₁Ēhd 2, the state after parsing is an error state (synchronization state). Notice that the Hamming distance between E₁E₂ and Ē₁E₂ is one, while the distance between E₁Ē₂ and Ē₁E₂ is two. Hence, the choice of E₁=E₂ is better, as the probability of ending up with synchronization state is larger. A similar analysis can be applied to the other codewords to show that Eᵢ=E₁ is the best choice since it maximizes the probability of returning into synchronization state.

According to the aforementioned discussion, it has been shown that for any source with PMF satisfying Equation (34), the best and the worst error recover performance for the case of bit inversion among all Huffman codes, respectively, results from the stable code and the unstable code configuration. This confirms the aforementioned conjecture. In addition, suppose for a source, there exists one Huffman code with length vector

$$( \underbrace{1 , 1 , … , 1}_{N - 2} , 2 ) .$$

The above proof can be extended to show that, for this source, the stable (unstable, respectively) code has the best (worst) error recovery performance for the case of bit inversion among all the Huffman codes having the same length vector

$$( \underbrace{1 , 1 , … , 1}_{N - 2} , 2 ) .$$

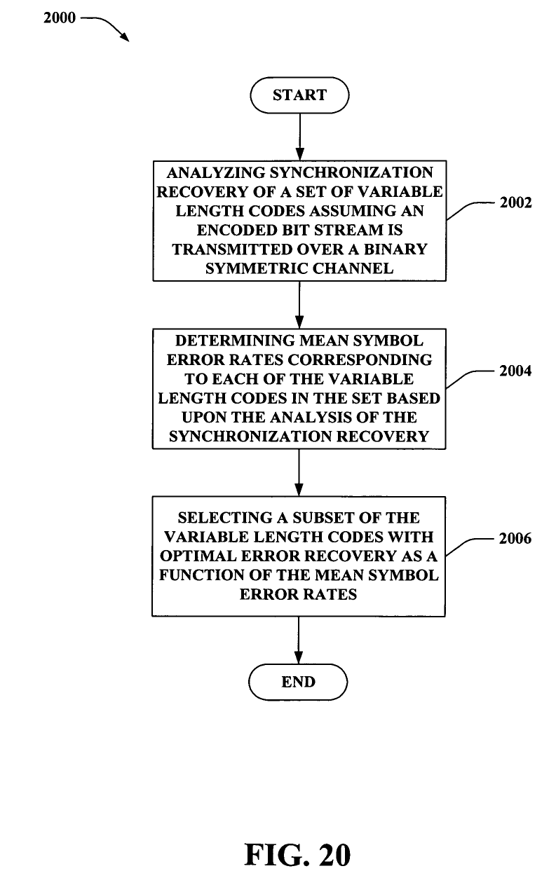

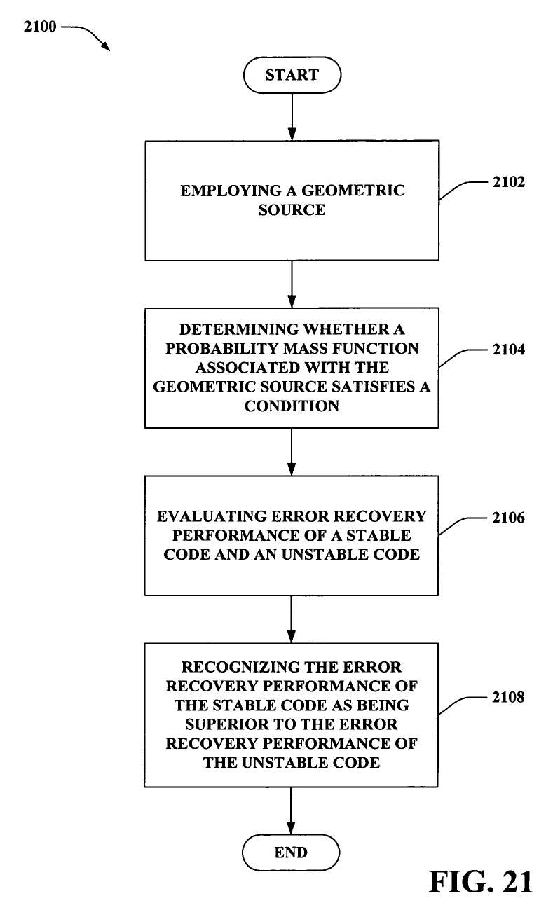

Referring now to FIGS. 20-21, methodologies that can be implemented in accordance with various aspects described herein are illustrated. While, for purposes of simplicity of explanation, the methodologies are shown and described as a series of blocks, it is to be understood and appreciated that the claimed subject matter is not limited by the order of the blocks, as some blocks may, in accordance with the claimed subject matter, occur in different orders and/or concurrently with other blocks from that shown and described herein. Moreover, not all illustrated blocks may be required to implement the methodologies in accordance with the claimed subject matter.

Furthermore, the claimed subject matter may be described in the general context of computer-executable instructions, such as program modules, executed by one or more components. Generally, program modules include routines, programs, objects, data structures, etc., that perform particular tasks or implement particular abstract data types. Typically the functionality of the program modules may be combined or distributed as desired in various embodiments. Furthermore, as will be appreciated various portions of the disclosed systems above and methods below may include or consist of artificial intelligence or knowledge or rule based components, sub-components, processes, means, methodologies, or mechanisms (e.g., support vector machines, neural networks, expert systems, Bayesian belief networks, fuzzy logic, data fusion engines, classifiers, . . . ). Such components, inter alia, can automate certain mechanisms or processes performed thereby to make portions of the systems and methods more adaptive as well as efficient and intelligent.

Referring now to FIG. 20, illustrated is an example methodology 2000 that facilitates optimizing error recovery performance based upon selection of variable length code utilized for encoding and decoding data. At 2002, synchronization recovery of a set of variable length codes (VLCs) can be analyzed while assuming an encoded bit is transmitted over a binary symmetric channel (BSC). Variable length codes can be utilized to encode inputted symbols for transmission over the channel. Further, variable length codes can be employed to decode data received via the channel to yield decoded symbols. At 2004, mean symbol error rates corresponding to each of the variable length codes in the set can be determined based upon the analysis of the synchronization recovery. For example, the mean symbol error rate can be defined as

$$μ = {lim}_{n \to ∞} \frac{E \{ T ( n ) \}}{n} ,$$

where T(n) is a total error propagation length, which is the total number of incorrectly decoded symbols when an input symbol length is n. Further, the mean symbol error rate for a variable length code can be determined by evaluating μ=1−u_{N} when the variable length code encoded bit stream is transmitted over BSC, where u_{N} is the last element of the Perron-Frobenius (PF) left eigenvector u of II, and II={πᵢⱼ} and is an N×N extended transition matrix. Moreover, variance of symbol error rates associated with each of the variable length codes in the set can be evaluated. By way of illustration, the variance of symbol error rate can be defined as

$${σ}^{2} = {lim}_{n \to ∞} \frac{{σ}_{T}^{2} ( n )}{{n}^{2}} ,$$

where σ_{T}²(n) denotes the variance of T(n). Further, the variance of symbol error rate for a variable length code can be given by σ²=0 when the variable length code encoded bit stream is transmitted over BSC. According to another illustration, a mean error propagation length obtained under a single inversion error assumption can be generated as a scaled value of the mean symbol error rate as a crossover probability of BSC tends to zero. At 2006, a subset of the variable length codes with optimal error recovery can be selected as a function of the mean symbol error rates. Further, the subset can be selected based upon the variance of symbol error rates and/or the mean error propagation length.

Now referring to FIG. 21, illustrated is a methodology 2100 that facilitates analyzing error recovery performance of variable length codes. At 2102, a geometric source can be employed. At 2104, a determination can be effectuated as to whether a probability mass function associated with the geometric source satisfies a condition. For example, the condition for the probability mass function can be

$${p}_{k} > {\sum }_{i = k + 2}^{N} {p}_{i} ,$$

for k=1, 2,. . . , N−3, where pᵢ is the occurrence probability of the ith symbol and N is the alphabet size. At 2106, error recovery performance of a stable code and an unstable code can be evaluated. For instance, the evaluation can be based upon considerations of mean error propagation length; however, the claimed subject matter is not so limited as mean symbol error rate, variance of symbol error rate, and so forth can additionally or alternatively be utilized. At 2108, the error recovery performance of the stable code can be recognized as being superior to the error recovery performance of the unstable code. According to another example, the stable code can be determined to yield the best error recovery performance among Huffman codes for the Geometric source under bit inversion, and the unstable code can be determined to yield the worst error recovery performance among Huffman codes for the Geometric source under bit inversion.

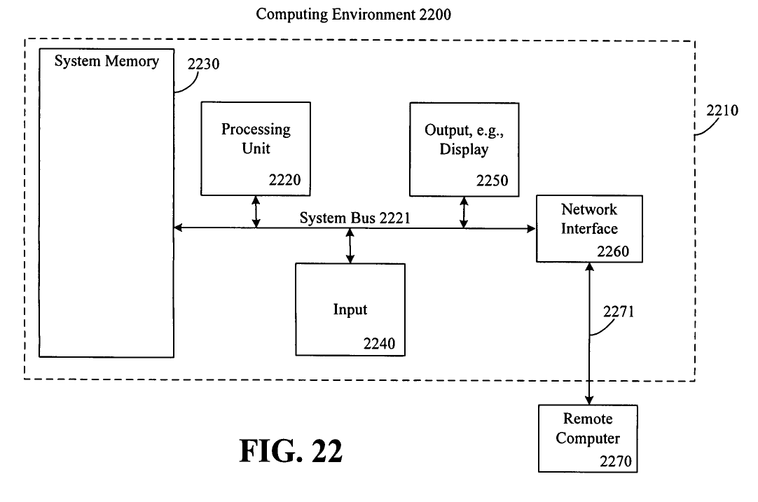

Turning to FIG. 22, an exemplary non-limiting computing system or operating environment in which various aspects described herein can be implemented is illustrated. One of ordinary skill in the art can appreciate that handheld, portable and other computing devices and computing objects of all kinds are contemplated for use in connection with the claimed subject matter, e.g., anywhere that a communications system may be desirably configured. Accordingly, the below general purpose remote computer described below in FIG. 22 is but one example of a computing system in which the claimed subject matter can be implemented.

Although not required, the claimed subject matter can partly be implemented via an operating system, for use by a developer of services for a device or object, and/or included within application software that operates in connection with one or more components of the claimed subject matter. Software may be described in the general context of computer-executable instructions, such as program modules, being executed by one or more computers, such as clients, servers, mobile devices, or other devices. Those skilled in the art will appreciate that the claimed subject matter can also be practiced with other computer system configurations and protocols, where non-limiting implementation details are given.

FIG. 22 thus illustrates an example of a suitable computing system environment 2200 in which the claimed subject matter may be implemented, although as made clear above, the computing system environment 2200 is only one example of a suitable computing environment for a media device and is not intended to suggest any limitation as to the scope of use or functionality of the claimed subject matter. Further, the computing environment 2200 is not intended to suggest any dependency or requirement relating to the claimed subject matter and any one or combination of components illustrated in the example operating environment 2200.

With reference to FIG. 22, an example of a remote device for implementing various aspects described herein includes a general purpose computing device in the form of a computer 2210. Components of computer 2210 can include, but are not limited to, a processing unit 2220, a system memory 2230, and a system bus 2221 that couples various system components including the system memory to the processing unit 2220. The system bus 2221 can be any of several types of bus structures including a memory bus or memory controller, a peripheral bus, and a local bus using any of a variety of bus architectures.

Computer 2210 can include a variety of computer readable media. Computer readable media can be any available media that can be accessed by computer 221 0. By way of example, and not limitation, computer readable media can comprise computer storage media and communication media. Computer storage media includes volatile and nonvolatile as well as removable and non-removable media implemented in any method or technology for storage of information such as computer readable instructions, data structures, program modules or other data. Computer storage media includes, but is not limited to, RAM, ROM, EEPROM, flash memory or other memory technology, CDROM, digital versatile disks (DVD) or other optical disk storage, magnetic cassettes, magnetic tape, magnetic disk storage or other magnetic storage devices, or any other medium which can be used to store the desired information and which can be accessed by computer 2210. Communication media can embody computer readable instructions, data structures, program modules or other data in a modulated data signal such as a carrier wave or other transport mechanism and can include any suitable information delivery media.

The system memory 2230 can include computer storage media in the form of volatile and/or nonvolatile memory such as read only memory (ROM) and/or random access memory (RAM). A basic input/output system (BIOS), containing the basic routines that help to transfer information between elements within computer 2210, such as during start-up, can be stored in memory 2230. Memory 2230 can also contain data and/or program modules that are immediately accessible to and/or presently being operated on by processing unit 2220. By way of non-limiting example, memory 2230 can also include an operating system, application programs, other program modules, and program data.

The computer 2210 can also include other removable/non-removable, volatile/nonvolatile computer storage media. For example, computer 2210 can include a hard disk drive that reads from or writes to non-removable, nonvolatile magnetic media, a magnetic disk drive that reads from or writes to a removable, nonvolatile magnetic disk, and/or an optical disk drive that reads from or writes to a removable, nonvolatile optical disk, such as a CD-ROM or other optical media. Other removable/non-removable, volatile/nonvolatile computer storage media that can be used in the exemplary operating environment include, but are not limited to, magnetic tape cassettes, flash memory cards, digital versatile disks, digital video tape, solid state RAM, solid state ROM and the like. A hard disk drive can be connected to the system bus 2221 through a non-removable memory interface such as an interface, and a magnetic disk drive or optical disk drive can be connected to the system bus 2221 by a removable memory interface, such as an interface.

A user can enter commands and information into the computer 2210 through input devices such as a keyboard or a pointing device such as a mouse, trackball, touch pad, and/or other pointing device. Other input devices can include a microphone, joystick, game pad, satellite dish, scanner, or the like. These and/or other input devices can be connected to the processing unit 2220 through user input 2240 and associated interface(s) that are coupled to the system bus 2221, but can be connected by other interface and bus structures, such as a parallel port, game port or a universal serial bus (USB). A graphics subsystem can also be connected to the system bus 2221. In addition, a monitor or other type of display device can be connected to the system bus 2221 via an interface, such as output interface 2250, which can in turn communicate with video memory. In addition to a monitor, computers can also include other peripheral output devices, such as speakers and/or a printer, which can also be connected through output interface 2250.

The computer 2210 can operate in a networked or distributed environment using logical connections to one or more other remote computers, such as remote computer 2270, which can in turn have media capabilities different from device 22 10. The remote computer 2270 can be a personal computer, a server, a router, a network PC, a peer device or other common network node, and/or any other remote media consumption or transmission device, and can include any or all of the elements described above relative to the computer 22 10. The logical connections depicted in FIG. 22 include a network 2271, such local area network (LAN) or a wide area network (WAN), but can also include other networks/buses. Such networking environments are commonplace in homes, offices, enterprise-wide computer networks, intranets and the Internet.

When used in a LAN networking environment, the computer 2210 is connected to the LAN 2271 through a network interface or adapter. When used in a WAN networking environment, the computer 2210 can include a communications component, such as a modem, or other means for establishing communications over the WAN, such as the Internet. A communications component, such as a modem, which can be internal or external, can be connected to the system bus 2221 via the user input interface at input 2240 and/or other appropriate mechanism. In a networked environment, program modules depicted relative to the computer 2210, or portions thereof, can be stored in a remote memory storage device. It should be appreciated that the network connections shown and described are exemplary and other means of establishing a communications link between the computers can be used.

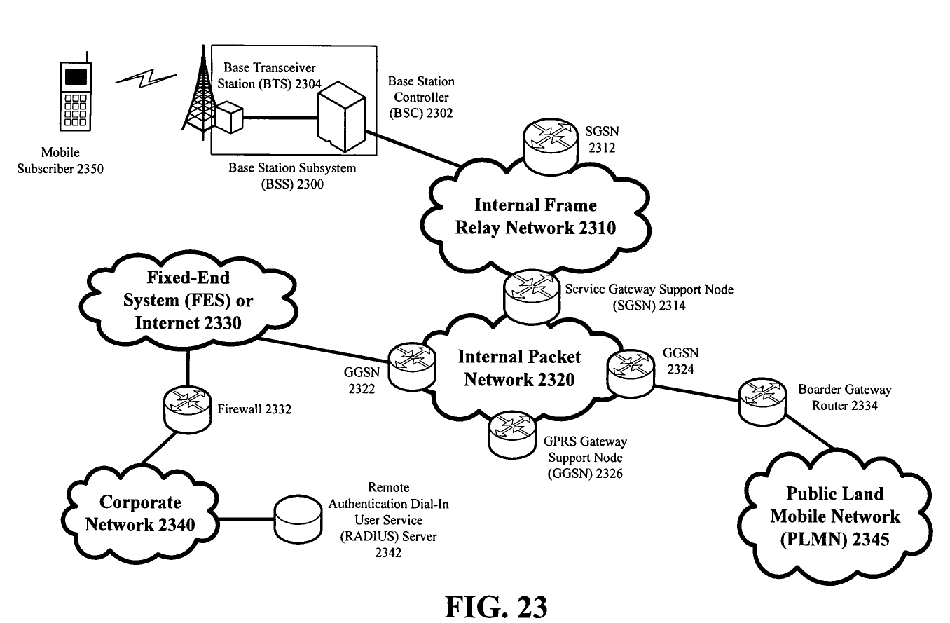

Turning now to FIG. 23, an overview of a network environment in which the claimed subject matter can be implemented is illustrated. The above-described systems and methodologies for timing synchronization may be applied to any wireless communication network; however, the following description sets forth an exemplary, non-limiting operating environment for said systems and methodologies. The below-described operating environment should be considered non-exhaustive, and thus the below-described network architecture is merely an example of a network architecture into which the claimed subject matter can be incorporated. It is to be appreciated that the claimed subject matter can be incorporated into any now existing or future alternative architectures for communication networks as well.

FIG. 23 illustrates various aspects of the global system for mobile communication (GSM). GSM is one of the most widely utilized wireless access systems in today's fast growing communications systems. GSM provides circuit-switched data services to subscribers, such as mobile telephone or computer users. General Packet Radio Service (“GPRS”), which is an extension to GSM technology, introduces packet switching to GSM networks. GPRS uses a packet-based wireless communication technology to transfer high and low speed data and signaling in an efficient manner. GPRS optimizes the use of network and radio resources, thus enabling the cost effective and efficient use of GSM network resources for packet mode applications.

As one of ordinary skill in the art can appreciate, the exemplary GSM/GPRS environment and services described herein can also be extended to 3G services, such as Universal Mobile Telephone System (“UMTS”), Frequency Division Duplexing (“FDD”) and Time Division Duplexing (“TDD”), High Speed Packet Data Access (“HSPDA”), cdma2000 1×Evolution Data Optimized (“EVDO”), Code Division Multiple Access-2000 (“cdma2000 3×”), Time Division Synchronous Code Division Multiple Access (“TD-SCDMA”), Wideband Code Division Multiple Access (“WCDMA”), Enhanced Data GSM Environment (“EDGE”), International Mobile Telecommunications-2000 (“IMT-2000”), Digital Enhanced Cordless Telecommunications (“DECT”), etc., as well as to other network services that shall become available in time. In this regard, the timing synchronization techniques described herein may be applied independently of the method of data transport, and does not depend on any particular network architecture or underlying protocols.

FIG. 23 depicts an overall block diagram of an exemplary packet-based mobile cellular network environment, such as a GPRS network, in which the claimed subject matter can be practiced. Such an environment can include a plurality of Base Station Subsystems (BSS) 2300 (only one is shown), each of which can comprise a Base Station Controller (BSC) 2302 serving one or more Base Transceiver Stations (BTS) such as BTS 2304. BTS 2304 can serve as an access point where mobile subscriber devices 2350 become connected to the wireless network. In establishing a connection between a mobile subscriber device 2350 and a BTS 2304, one or more timing synchronization techniques as described supra can be utilized.

In one example, packet traffic originating from mobile subscriber 2350 is transported over the air interface to a BTS 2304, and from the BTS 2304 to the BSC 2302. Base station subsystems, such as BSS 2300, are a part of internal frame relay network 2310 that can include Service GPRS Support Nodes (“SGSN”) such as SGSN 2312 and 2314. Each SGSN is in turn connected to an internal packet network 2320 through which a SGSN 2312, 2314, etc., can route data packets to and from a plurality of gateway GPRS support nodes (GGSN) 2322, 2324, 2326, etc. As illustrated, SGSN 2314 and GGSNs 2322, 2324, and 2326 are part of internal packet network 2320. Gateway GPRS serving nodes 2322, 2324 and 2326 can provide an interface to external Internet Protocol (“IP”) networks such as Public Land Mobile Network (“PLMN”) 2345, corporate intranets 2340, or Fixed-End System (“FES”) or the public Internet 2330. As illustrated, subscriber corporate network 2340 can be connected to GGSN 2322 via firewall 2332; and PLMN 2345 can be connected to GGSN 2324 via boarder gateway router 2334. The Remote Authentication Dial-In User Service (“RADIUS”) server 2342 may also be used for caller authentication when a user of a mobile subscriber device 2350 calls corporate network 2340.

Generally, there can be four different cell sizes in a GSM network—macro, micro, pico, and umbrella cells. The coverage area of each cell is different in different environments. Macro cells can be regarded as cells where the base station antenna is installed in a mast or a building above average roof top level. Micro cells are cells whose antenna height is under average roof top level; they are typically used in urban areas. Pico cells are small cells having a diameter is a few dozen meters; they are mainly used indoors. On the other hand, umbrella cells are used to cover shadowed regions of smaller cells and fill in gaps in coverage between those cells.

The word “exemplary” is used herein to mean serving as an example, instance, or illustration. For the avoidance of doubt, the subject matter disclosed herein is not limited by such examples. In addition, any aspect or design described herein as “exemplary” is not necessarily to be construed as preferred or advantageous over other aspects or designs, nor is it meant to preclude equivalent exemplary structures and techniques known to those of ordinary skill in the art. Furthermore, to the extent that the terms “includes,” “has,” “contains,” and other similar words are used in either the detailed description or the claims, for the avoidance of doubt, such terms are intended to be inclusive in a manner similar to the term “comprising” as an open transition word without precluding any additional or other elements.

The aforementioned systems have been described with respect to interaction between several components. It can be appreciated that such systems and components can include those components or specified sub-components, some of the specified components or sub-components, and/or additional components, and according to various permutations and combinations of the foregoing. Sub-components can also be implemented as components communicatively coupled to other components rather than included within parent components (hierarchical). Additionally, it should be noted that one or more components may be combined into a single component providing aggregate functionality or divided into several separate sub-components, and that any one or more middle layers, such as a management layer, may be provided to communicatively couple to such sub-components in order to provide integrated functionality. Any components described herein may also interact with one or more other components not specifically described herein but generally known by those of skill in the art.

In view of the exemplary systems described supra, methodologies that may be implemented in accordance with the described subject matter will be better appreciated with reference to the flowcharts of the various figures. While for purposes of simplicity of explanation, the methodologies are shown and described as a series of blocks, it is to be understood and appreciated that the claimed subject matter is not limited by the order of the blocks, as some blocks may occur in different orders and/or concurrently with other blocks from what is depicted and described herein. Where non-sequential, or branched, flow is illustrated via flowchart, it can be appreciated that various other branches, flow paths, and orders of the blocks, may be implemented which achieve the same or a similar result. Moreover, not all illustrated blocks may be required to implement the methodologies described hereinafter.

In addition to the various embodiments described herein, it is to be understood that other similar embodiments can be used or modifications and additions can be made to the described embodiment(s) for performing the same or equivalent function of the corresponding embodiment(s) without deviating there from. Still further, multiple processing chips or multiple devices can share the performance of one or more functions described herein, and similarly, storage can be effected across a plurality of devices. Accordingly, no single embodiment shall be considered limiting, but rather the various embodiments and their equivalents should be construed consistently with the breadth, spirit and scope in accordance with the appended claims.

### Appendix A—Proof of the Expression Equivalence Between E_{rec} and epl(c)

In this Appendix, it is shown that E_{rec}, after some transformations, has the same form as epl(c), only with different definition of a transition matrix.

E_{rec} can be as follows:

$${E}_{rec} = 1 \cdot {p}_{0} + {lim}_{n \to ∞} {\sum }_{i = 1}^{n} ( i + 1 ) p ( i ) s$$

where p₀=Pr{I→S}, with I and S, respectively, denoting the initial state and the synchronization state; p(i)=(p₁(i), p₂(i), . . . , p_{M}(i)), with pⱼ(i) being the probability of ending up with ESⱼ after parsing ith codewords; and s=(s₁, s₂, . . . , s_{M})′, with sᵢ=Pr{ESᵢ→S}.

Notice p₀=1−p(1)1_{M} and s=1_{M}−T1_{M}, where T is the error state transition matrix. It follows that

$$\begin{matrix}{E}_{rec} = 1 \cdot {p}_{0} + {lim}_{n \to ∞} {\sum }_{i = 1}^{n} ( i + 1 ) p ( i ) s \\ = 1 - p ( 1 ) {1}_{M} + {lim}_{n \to ∞} {\sum }_{i = 1}^{n} \\ [ ( i + 1 ) p ( 1 ) {T}^{i - 1} {1}_{M} - ( i + 1 ) p ( 1 ) {T}^{i} {1}_{M} ] \\ = 1 - p ( 1 ) {1}_{M} + 2 p ( 1 ) {1}_{M} - 2 p ( 1 ) T {1}_{M} + 3 p ( 1 ) \\ T {1}_{M} - 3 p ( 1 ) {T}^{2} {1}_{M} + … \\ = 1 + p ( 1 ) {1}_{M} + p ( 1 ) T {1}_{M} + p ( 1 ) {T}^{2} {1}_{M} + … \\ = 1 + p ( 1 ) {( 1 - T )}^{- 1} {1}_{M}\end{matrix} \qquad ( 72 )$$

where the last equality holds if (I−T)⁻¹ exists. Thus, the expression of epl(c) has the same form as that of Equation (72), although the definition of the transition matrix is different.

### Appendix B. Proof of Lemma 1

Let the alphabet size of the VLC be N, and the corresponding N×N extended transition matrix be II={π_{i,j}}.

As the probability from any error state to synchronization state is non-zero, for any 1≦i≦N−2, there exists an integer 1≦m<∞ such that π_{i,N-1}^{(m)}>0.

Since the probability of visiting any error state from synchronization state is non-zero, for any 1≦j≦N−2, there exists an integer 1≦k<∞ such that π_{n-1,j}^{(k)}>0 and π_{N,j}^{(k)}>0.

Then, for any ordered pair (i,j), 1≦i,j≦N−2, this yields π_{i,j}^{(m+k)}≧π_{i,N-1}^{(m)}π_{N-1,j}^{(k)}>0 where the first inequality holds from the rule of matrix multiplication and the non-negativity of II.

As the VLC is exhaustive, the corresponding binary branching tree is complete, which follows that π_{N-1,N-1}=π_{N,N-1}>0. It is also evident that π_{N-1,N}=π_{N,N}>0. Therefore, for any ordered pair (i,j), 1≦i, j≦N, there exists an integer 1≦q≡q(i,j)<∞ such that π_{i,j}^{(q)}>0. Then, II is an irreducible matrix. Notice that Tr(II)>0, which implies II is primitive.

### Appendix C. Proof of Lemma 2

Since II is a primitive matrix from Lemma 1, according to Corollary 1 of the Perron-Frobenius Theorem, the following is obtained:

$${min}_{i} {\sum }_{j = 1}^{N} {π}_{i , j} \leq λ \leq {max}_{i} {\sum }_{j = 1}^{N} {π}_{i , j} \qquad ( 73 )$$

with equality on either side implying equality throughout, where λ is the PF eigenvalue. Notice that II is also a stochastic matrix, then any row sums up to one, which implies λ=1. Clearly, the associated PF right eigenvector is v=1_{N}. Suppose the distinct eigenvalues of II are λ, λ₂, . . . , λₗ, where l≦N, and λ>|λ₂|≧|λ₃|≧. . . ≧|λₗ|. As lim_{k→∞} |λ₂|^{k}=0, it can be seen that:

$$\begin{matrix}{lim}_{k \to ∞} {\prod }^{k} = {lim}_{k \to ∞} {λ}^{k} {vu}^{′} \\ = {1}_{N} {u}^{′}\end{matrix} \qquad ( 74 )$$

This completes the proof.

### Appendix D. Proof of Lemma 3

Notice that from any error state, it is impossible to jump in one step to Sync₁. In addition, the transition probability from Sync₁ to any state is equal to that from Sync₂ to that state. It follows that:

π_{j,N}=0 for 1≦j≦N−2 π_{N-1,j}=π_{N,j} for 1≦j≦N (75)

Since the eigenvalue associated with u=(u₁, u₂, . . . , u_{N})′ is λ=1,

(I−II′)u=0 (76)

e.g.,

$$( \begin{matrix}1 - {π}_{1 , 1} & - {π}_{2 , 1} & … & - {π}_{N , 1} \\ - {π}_{1 , 2} & 1 - {π}_{2 , 2} & … & - {π}_{N , 2} \\ ⋮ & ⋮ & ⋰ & ⋮ \\ - {π}_{1 , N} & - {π}_{2 , N} & … & 1 - {π}_{N , N}\end{matrix} ) ( \begin{matrix}{u}_{1} \\ {u}_{2} \\ ⋮ \\ {u}_{N}\end{matrix} ) = 0 \qquad ( 77 )$$

Using the last row, and notice Equation (75), the following is obtained:

−π_{N-1,N}u_{N-1}+(1−π_{N,N})u_{N}=0 (78)

Then,

(u_{N-1}+u_{N})π_{N-1,N}=u_{N} (79)

Further, since

u′s₁=(u_{N-1}+u_{N})π_{N-1,N} (80)

this immediately completes the proof.

### Appendix E. Proof of Lemma 4

By definition, π_{N,N}=Pr{Sync₁→Sync₁}, then,

$${π}_{N , N} = {\sum }_{i = 1}^{N} p ( {a}_{i} ) {( 1 - {p}_{e} )}^{l ( {c}_{i} )} \qquad ( 81 )$$

Hence,

$$\begin{matrix}{lim}_{{p}_{e} \to ∞} \frac{1 - {π}_{N , N}}{{p}_{e} {L}_{X} ( C )} = {lim}_{{p}_{e} \to 0} \frac{1 - {\sum }_{i = 1}^{N} p ( {a}_{i} ) {( 1 - {p}_{e} )}^{l ( {c}_{i} )}}{{p}_{e} {L}_{X} ( C )} \\ = {lim}_{{p}_{e} \to 0} \frac{{\sum }_{i = 1}^{N} p ( {a}_{i} ) l ( {c}_{i} ) {( 1 - {p}_{e} )}^{l ( {c}_{i} ) - 1}}{{L}_{X} ( C )} \\ = 1\end{matrix} \qquad ( 82 )$$

This completes the proof of Equation (6).

From Equation (3), the following can be obtained:

$$\begin{matrix}{π}_{i , j} = {\sum }_{( h , k ) : {θ}_{h} ∈ {Ω}_{θ} ( i , j ) , {c}_{k} ∈ C , l ( {c}_{k} ) = l ( {θ}_{h} )} p ( {a}_{k} ) {p}_{e}^{{d}_{H} ( {θ}_{h} , {c}_{k} )} \\ {( 1 - {p}_{e} )}^{l ( {c}_{k} ) - {d}_{H} ( {θ}_{h} , {c}_{k} )} \\ = {\sum }_{( h , k ) : {θ}_{h} ∈ {Ω}_{θ} ( i , j ) , {c}_{k} ∈ C , l ( {c}_{k} ) = l ( {θ}_{h} ) , {d}_{H} ( {θ}_{h} , {c}_{k} ) = 0} p ( {a}_{k} ) {{p}_{e}^{0} ( 1 - {p}_{e} )}^{l ( {c}_{k} )} + \\ {\sum }_{( h , k ) : {θ}_{h} ∈ {Ω}_{θ} ( i , j ) , {c}_{k} ∈ C , l ( {c}_{k} ) = l ( {θ}_{k} ) , {d}_{H} ( {θ}_{h} , {c}_{k} ) = 1} p ( {a}_{k} ) {{p}_{e} ( 1 - {p}_{e} )}^{l ( {c}_{k} ) - 1} \\ ⋮ + \\ {\sum }_{( h , k ) : {θ}_{h} ∈ {Ω}_{θ} ( i , j ) , {c}_{k} ∈ C , l ( {c}_{k} ) = l ( {θ}_{h} ) , {d}_{H} ( {θ}_{h} , {c}_{k} ) = {L}_{max}} p ( {a}_{k} ) {p}_{e}^{{L}_{max}} \\ {( 1 - {p}_{e} )}^{l ( {c}_{k} ) - {L}_{max}}\end{matrix} \qquad ( 83 )$$

Since at least one bit error occurs when there is a state transition from a synchronization state to an error state, for π_{Nj}, 1≦j≦N−2, the first term in the last equation is equal to zero. It follows that

$${lim}_{{p}_{e} \to 0} \frac{{π}_{N , j}}{{p}_{e} {L}_{X} ( C )} = {\sum }_{( h , k ) : {θ}_{h} ∈ {Ω}_{θ} ( N , j ) , {c}_{k} ∈ C , l ( {a}_{k} ) = l ( {θ}_{h} ) , {d}_{H} ( {θ}_{h} , {a}_{k} ) = 1} \frac{p ( {a}_{k} )}{{L}_{X} ( C )} \qquad ( 84 )$$

where 1≦j≦N−2. This completes the proof of Equation (7).

### Appendix F. Proof of Lemma 5

$$\begin{matrix}Cov \{ T ( n ) , Δ ( n ) \} = E \{ Δ ( n ) T ( n ) \} - E \{ Δ ( n ) \} E \{ T ( n ) \} \\ = E \{ T ( n ) \vert Δ ( n ) = 1 \} Pr \{ Δ ( n ) = 1 \} - \\ Pr \{ Δ ( n ) = 1 \} E \{ T ( n ) \} \\ = Pr \{ Δ ( n ) = 1 \} [ E \{ T ( n ) \vert Δ ( n ) = 1 \} - E \{ T ( n ) \} ]\end{matrix} \qquad ( 85 )$$

Define δ(i)=E{T(i)|Δ(n)=1}−E{T(i)}, 1≦i≦n. From Equation (11), the following can be yielded:

δ(i)=δ(i−1)+E{Δ(i−1)|Δ(n)=1}−E{Δ(i−1)}, 2≦i≦n (86)

It follows that

$$\begin{matrix}δ ( n ) = δ ( 1 ) + {\sum }_{i = 1}^{n - 1} [ E \{ Δ ( i ) \vert Δ ( n ) = 1 \} - E \{ Δ ( i ) \} ] \\ = δ ( 1 ) + {\sum }_{i = 1}^{n - 1} [ Pr \{ Δ ( i ) = 1 \vert Δ ( n ) = 1 \} - Pr \{ Δ ( i ) = 1 \} ]\end{matrix} \qquad ( 87 )$$

Notice that

$$\begin{matrix}Pr \{ Δ ( i ) = 1 \vert Δ ( n ) = 1 \} = 1 - Pr \{ Δ ( i ) = 0 \vert Δ ( n ) = 1 \} \\ = 1 - \frac{Pr \{ Δ ( n ) = 1 \vert Δ ( i ) = 0 \} Pr \{ Δ ( i ) = 0 \}}{Pr \{ Δ ( n ) = 1 \}} \\ = 1 - \frac{[ 1 - Pr \{ Δ ( n - i - 1 ) = 0 \} ] Pr \{ Δ ( n ) = 0 \}}{Pr \{ Δ ( n ) = 1 \}}\end{matrix} \qquad ( 88 )$$

Substituting (88) into (87), and making some simplifications yields the following:

$$δ ( n ) = δ ( 1 ) + {\sum }_{i = 1}^{n - 1} \frac{\begin{matrix}Pr \{ Δ ( i ) = 0 \} \\ [ Pr \{ Δ ( n - i - 1 ) = 0 \} - Pr \{ Δ ( n ) = 0 \} ]\end{matrix}}{Pr \{ Δ ( n ) = 1 \}} \qquad ( 89 )$$

Substituting (89) into (85), and making some simplifications results in the following:

$$Cov \{ Δ ( n ) , T ( n ) \} = \underbrace{Pr \{ Δ ( n ) = 1 \} δ ( 1 )}_{( I )} + \underbrace{{\sum }_{i = 1}^{n - 1} Pr \{ Δ ( i ) = 0 \} [ Pr \{ Δ ( n - i - 1 ) = 0 \} - Pr \{ Δ ( n ) = 0 \} ]}_{( II )} \qquad ( 90 )$$

It is easy to find that, for the first term,

$${lim}_{n \to ∞} \frac{( I )}{n} = 0 \qquad ( 91 )$$

For the second term,

$$0 \leq {lim}_{n \to ∞} \frac{\vert ( II ) \vert}{n} \leq {lim}_{n \to ∞} \frac{{\sum }_{i = 1}^{n - 1} \begin{matrix}\vert Pr \{ Δ ( i ) = 0 \} \vert \\ \vert Pr \{ Δ ( n - i - 1 ) = 0 \} - Pr \{ Δ ( n ) = 0 \} \vert\end{matrix}}{n} \leq {lim}_{n \to ∞} \frac{{\sum }_{i = 1}^{n - 1} \vert Pr \{ Δ ( n - i - 1 ) = 0 \} - Pr \{ Δ ( n ) = 0 \} \vert}{n} = {lim}_{n \to ∞} \frac{{\sum }_{i = 1}^{n - 2} \vert Pr \{ Δ ( n - i - 1 ) = 0 \} - Pr \{ Δ ( n ) = 0 \} \vert}{n} {=}^{( a )} {lim}_{n \to ∞} \frac{\vert p ( 1 ) {\sum }_{i = 0}^{n - 3} {\prod }^{i} {s}_{1} - ( n - 2 ) p ( 1 ) {\prod }^{n - 1} {s}_{1} \vert}{n} = {lim}_{n \to ∞} \frac{\vert p ( 1 ) n {\prod }^{∞} {s}_{1} - ( n - 2 ) p ( 1 ) {\prod }^{∞} {s}_{1} \vert}{n} {=}^{( b )} 0 \qquad ( 92 )$$

where (a) follows from Equation (12), and (b) follows from Lemma 2.

Hence,

$${lim}_{n \to ∞} \frac{\vert ( II ) \vert}{n} = 0.$$

### Since

$$- {lim}_{n \to ∞} \frac{\vert ( II ) \vert}{n} \leq {lim}_{n \to ∞} \frac{( II )}{n} \leq {lim}_{n \to ∞} \frac{\vert ( II ) \vert}{n} \qquad ( 93 )$$

which leads to the following:

$${lim}_{n \to ∞} \frac{( II )}{n} = 0 \qquad ( 94 )$$

Therefore,

$${lim}_{n \to ∞} \frac{Cov \{ T ( n ) , Δ ( n ) \}}{n} = 0 ,$$

and this completes the proof.

What is claimed is:

1. A system that evaluates synchronization recovery of variable length codes, comprising:
a transmitter that sends data encoded utilizing a variable length code over a channel;
a receiver that obtains data sent over the channel and decodes the data by employing the variable length code; and
an error recovery optimization component that analyzes synchronization recovery capability of the variable length code, the error recovery optimization component determines at least one of a mean symbol error rate or a variance of symbol error rate associated with the variable length code.

2. The system of claim 1, the error recovery optimization component utilizes the Perron-Frobenius Theorem to determine the mean symbol error rate.

3. The system of claim 1, the error recovery optimization component selects the variable length code used by at least one of the transmitter and the receiver based upon the analysis, the selected variable length code provides optimized error recovery.

4. The system of claim 3, the error recovery optimization component initializes the at least one of the transmitter and the receiver by selecting the variable length code prior to operation of the transmitter and the receiver.

5. The system of claim 3, the error recovery optimization component provides feedback control to enable convergence towards employing an optimal variable length code.

6. The system of claim 1, the error recovery optimization component determines the mean symbol error rate by evaluating μ=1−u_{N} when the variable length code encoded bit stream is transmitted over a binary symmetric channel, where u_{N} is the last element of a Perron-Frobenius (PF) left eigenvector u of II, and II={π_{i,j}} and is an N×N extended transition matrix.

7. The system of claim 1, the error recovery optimization component determines the variance of symbol error rate to be zero when the variable length code encoded bit stream is transmitted over a binary symmetric channel.

8. The system of claim 1, the error recovery optimization component further analyzes synchronization recovery capability of the variable length code by determining a mean error propagation length.

9. The system of claim 8, the error recovery optimization component obtains the mean error propagation length under a single inversion error assumption as a function of a scaled value of the mean symbol error rate as a crossover probability of a binary symmetric channel tends to zero.

10. The system of claim 1, the variable length code being associated with at least one of a five-character source, an English text source, or a Geometric source.

11. The system of claim 11, the error recovery optimization component determines that a stable code provides optimized error recovery performance in comparison to an unstable code for the Geometric source.

12. A method that facilitates optimizing error recovery performance based upon selection of variable length code utilized for encoding and decoding data, comprising:
analyzing synchronization recovery of a set of variable length codes assuming an encoded bit stream is transmitted over a binary symmetric channel;
determining mean symbol error rates corresponding to each of the variable length codes in the set based upon the analysis of the synchronization recovery; and
selecting a subset of the variable length codes with optimal error recovery as a function of the mean symbol error rates.

13. The method of claim 12, further comprising:
encoding inputted symbols for transmission over a channel by utilizing the selected subset of variable length codes; and
decoding data received via the channel by employing the selected subset of variable length codes to yield decoded symbols.

14. The method of claim 12, the mean symbol error rate being defined as
$$μ = {lim}_{n \to ∞} \frac{E \{ T ( n ) \}}{n} ,$$
where T(n) is a total error propagation length, which is a total number of incorrectly decoded symbols when an input symbol length is n.

15. The method of claim 12, determining the mean symbol error rates further comprises evaluating μ=1−u_{N} when the variable length code encoded bit stream is transmitted over the binary symmetric channel, where u_{N} is a last element of a Perron-Frobenius (PF) left eigenvector u of II, and II={π_{i,j}} and is an N×N extended transition matrix.

16. The method of claim 12, further comprising selecting the subset of the variable length codes based upon at least one of variance of symbol error rates or mean error propagation lengths associated with the variable length codes in the set.

17. The method of claim 16, the variance of symbol error rate being defined as
$${σ}^{2} = {lim}_{n \to ∞} \frac{{σ}_{T}^{2} ( n )}{{n}^{2}} ,$$
where σ_{T}²(n) denotes the variance of T(n), and σ²=0 when the variable length code encoded bit stream is transmitted over the binary symmetric channel.

18. The method of claim 16, the mean error propagation lengths obtained under a single inversion error assumption being generated as a scaled value of the corresponding mean symbol error rates as a crossover probability of the binary symmetric channel tends to zero.

19. The method of claim 12, further comprising:
employing a Geometric source;
determining whether a probability mass function associated with the Geometric source satisfies a condition;
evaluating error recovery performance of a stable code and an unstable code; and
recognizing the error recovery performance of the stable code as being superior to the error recovery performance of the unstable code.

20. A system that enables analyzing error recovery performance of variable length codes utilized for encoding and decoding data, comprising:
means for evaluating synchronization recovery of a set of variable length codes assuming an encoded bit stream is transmitted over a binary symmetric channel;
means for determining mean symbol error rates corresponding to each of the variable length codes in the set based upon at least one output of the means for evaluating synchronization recovery; and
means for selecting a subset of the variable length codes with optimal error recovery as a function of the mean symbol error rates.
